(19) United States
(12) Patent Application Publication
(10) Pub. No.: US 2025/0176160 A1
(43) Pub. Date: May 29, 2025

(54) SEMICONDUCTOR DEVICES AND MANUFACTURING METHODS THEREOF AND MEMORY SYSTEMS

(71) Applicant: YANGTZE MEMORY TECHNOLOGIES CO., LTD., Wuhan (CN)

(72) Inventors: Yuancheng YANG, Wuhan (CN); Lei LIU, Wuhan (CN); Changzhi SUN, Wuhan (CN); Wenxi ZHOU, Wuhan (CN); ZhiLiang XIA, Wuhan (CN); ZongLiang HUO, Wuhan (CN)

(21) Appl. No.: 18/671,773

(22) Filed: May 22, 2024

(30) Foreign Application Priority Data
Nov. 28, 2023 (CN) 2023116183868

(51) Int. Cl. H10B 12/00; H01L 29/66; H01L 29/786

(52) U.S. Cl. CPC H10B 12/312; H10B 12/0335; H10B 12/482; H10D 30/0321; H10D 30/6755; H10D 30/6757

(57) ABSTRACT

Semiconductor devices, manufacturing methods thereof and memory systems are provided. In one aspect, a semiconductor device includes: channel structures. wherein at least one of the channel structures includes a first side portion and a second side portion arranged along a first direction and a connection portion connected to first end portions of the first side portion and the second side portion in a second direction; first dielectric layers located on surfaces of the first side portion and the second side portion that are opposite to each other; and gate layers located on surfaces of the first dielectric layers and extending along a third direction, wherein the first direction, the second direction, and the third direction intersect with each other.

### CROSS-REFERENCE TO RELATED APPLICATIONS

The present application claims priority to Chinese Patent Application No. 2023116183868, which was filed Nov. 28, 2023, is titled “SEMICONDUCTOR DEVICE, MEMORY SYSTEM AND MANUFACTURING METHOD OF SEMICONDUCTOR DEVICE,” and is hereby incorporated herein by reference in its entirety.

### TECHNICAL FIELD

The present disclosure relates to semiconductors, and, in particular, to semiconductor devices, manufacturing methods thereof and memory systems.

### BACKGROUND

During an iterative development process of a semiconductor device (for example, DRAM), the semiconductor device is expected to have smaller footprint and higher unit storage density.

### SUMMARY

The present disclosure provides a semiconductor device, a memory system, and a manufacturing method of a semiconductor device which can at least partially solve the above-mentioned challenges existing in the related arts or other challenges in the art.

In a first aspect, some examples of the present disclosure provide a semiconductor device. The semiconductor device comprises: channel structures, at least one of the channel structures comprises: a first side portion and a second side portion arranged along a first direction; and a connection portion connected to first end portions of the first side portion and the second side portion in a second direction; first dielectric layers located on surfaces of the first side portion and the second side portion that are opposite to each other; and gate layers located on surfaces of the first dielectric layers and extending along a third direction, wherein the first direction, the second direction, and the third direction intersect with each other.

In some implementations, the channel structures are arranged as being spaced apart in the first direction, and the connection portions in the channel structures are not in contact with each other.

In some implementations, the semiconductor device further comprises: second end portions of the first side portion and the second side portion facing away from the connection portion; wherein a spacing distance between the first end portions of the first side portion and the second side portion, is smaller than a spacing distance between the second end portions of the first side portion and the second side portion.

In some implementations, a spacing distance between the first side portion and the second side portion in the first direction gradually increases along a direction opposite to the second direction.

In some implementations, surfaces of the gate layers close to the first side portion and the second side portion are concavo-convex-shaped on a plane perpendicular to the second direction.

In some implementations, the semiconductor device further comprises: a shielding structure located between the first side portion and the second side portion and comprising: a conductive structure extending along the third direction; and second dielectric layers located between the conductive structure and the first side portion and between the conductive structure and the second side portion.

In some implementations, a size of the conductive structure in the first direction gradually increases along a direction opposite to the second direction.

In some implementations, a material of the conductive structure comprises polycrystalline silicon or amorphous silicon.

In some implementations, the second dielectric layer is also located on an end surface of the conductive structure facing away from the connection portion.

In some implementations, the semiconductor device further comprises: a first isolation structure located between the first side portion and the second side portion and on a side of the conductive structure facing away from the connection portion; and a second isolation structure located between the connection portion and the conductive structure and on a side of the conductive structure close to the connection portion.

In some implementations, a material of the second isolation structure comprises a non-silicon oxide material.

In some implementations, the non-silicon oxide material is silicon nitride.

In some implementations, the semiconductor device further comprises: capacitor connection structures respectively connected to second end portions of the first side portion and the second side portion facing away from the connection portion.

In some implementations, at least one of the channel structures further comprises extending portions located on the second end portions, and the extending portions respectively extend along the first direction and directions facing away from the first side portion and the second side portion and are respectively in contact with the capacitor connection structures.

In some implementations, each of the gate layers comprises a first adhesion layer and a metal layer attached to each other, and the first adhesion layer is in contact with the first dielectric layer and extends to an end surface of the metal layer close to respective one of the capacitor connection structures.

In some implementations, the semiconductor device further comprises: an outer electrode layer located on a side of respective one of the capacitor connection structures facing away from the channel structure; an inner electrode located in the outer electrode layer; and an insulation layer located between the outer electrode layer and the inner electrode, wherein respective one of the capacitor connection structures is connected with the inner electrode.

In some implementations, the inner electrode is a pillar-shaped structure and at least partially penetrates through the outer electrode layer, wherein a size of the inner electrode on a plane perpendicular to the second direction gradually reduces along a direction opposite to the second direction.

In some implementations, the semiconductor device further comprises: a bit line extending along the first direction and connected with the connection portion.

In some implementations, the first side portion, the second side portion, and the connection portion are of an integral structure.

In some implementations, materials of the first side portion, the second side portion, and the connection portion comprise a metal oxide semiconductor.

In some implementations, the metal oxide semiconductor comprises an indium gallium zinc oxide (IGZO).

In some implementations, sizes of the first side portion and the second side portion in the first direction respectively are 3-10 nm.

In some implementations, the size range of the first side portion in the first direction is 3 nm-10 nm; and the size range of the second side portion in the first direction is 3 nm-10 nm.

In some implementations, the channel structures are arranged as being spaced apart in the third direction; and the semiconductor device further comprises a third isolation structure located between adjacent channel structures, wherein a material of the third isolation structure comprises silicon nitride.

According to another aspect of the present disclosure, a memory system is provided. The memory system may include a semiconductor device. The semiconductor device may include channel structures. At least one of the channel structures may include a first side portion and a second side portion arranged along a first direction. The channel structure may further include a connection portion connected to first end portions of the first side portion and the second side portion in a second direction. The semiconductor device may include first dielectric layers located on surfaces of the first side portion and the second side portion that are opposite to each other. The semiconductor device may further include gate layers located on surfaces of the first dielectric layers and extending along a third direction. The first direction, the second direction, and the third direction intersect with each other. The memory system may further include a controller coupled to the semiconductor device and configured to control the semiconductor device to store data.

According to a further aspect of the present disclosure, a method of manufacturing a semiconductor device is provided. The manufacturing method of the semiconductor device comprises: forming a support structure extending along a third direction, wherein the support structure has a first sidewall and a second sidewall opposite to each other in a first direction and an end surface in a second direction; forming an initial channel structure covering the first sidewall, the second sidewall, and the end surface, and forming an initial first dielectric layer on a surface of the initial channel structure; discontinuously removing a portion of the initial channel structure and a portion of the initial first dielectric layer in the third direction to form a plurality of channel structures; forming gate layers extending along the third direction on surfaces of the initial first dielectric layer facing away from the first sidewall and the second sidewall; and removing a portion of the initial first dielectric layer corresponding to the end surface to expose the channel structures, wherein the first direction, the second direction, and the third direction intersect with each other.

In some implementations, forming the forming the support structure extending along the third direction comprises: forming a first isolation structure, a conductive structure, and a second isolation structure sequentially arranged along the second direction, wherein the first isolation structure, the conductive structure, and the second isolation structure all extend along the third direction; and forming second dielectric layers on sidewalls of the conductive structure opposite to each other in the first direction to form the support structure.

In some implementations, forming the forming the support structure extending along the third direction comprises: etching a sacrificial layer to form a trench extending along the third direction, wherein a first isolation structure is formed at a bottom of the trench; forming a second dielectric layer on a sidewall of the trench and a top surface of the first isolation structure, and forming a conductive structure inside the second dielectric layer; and forming a second isolation structure at a top of the trench to form the support structure.

In some implementations, before forming the forming the support structure extending along the third direction, the manufacturing method further comprises: forming an outer electrode layer on a side of a substrate; forming a plurality of inner electrodes in the outer electrode layer; and respectively forming a plurality of insulation layers between the outer electrode layer and the plurality of inner electrodes.

In some implementations, the manufacturing method further comprises: forming a capacitor dielectric layer covering the plurality of inner electrodes and the plurality of insulation layers; and forming a plurality of capacitor connection structures penetrating through the capacitor dielectric layer and respectively connected with the plurality of inner electrodes, wherein at least a portion of the support structure is located between adjacent capacitor connection structures in the first direction.

In some implementations, adjacent support structures are spaced apart with two of the capacitor connection structures in the first direction, wherein forming the initial channel structure covering the first sidewall, the second sidewall, and the end surface and forming the initial first dielectric layer on the surface of the initial channel structure comprises: forming the initial channel structure on surfaces of the capacitor dielectric layer and the capacitor connection structures, wherein discontinuously removing the portion of the initial channel structure and the portion of the initial first dielectric layer in the third direction to form a plurality of channel structures further comprises: removing at least a portion of the initial channel structure covering the surfaces of the capacitor dielectric layer and the capacitor connection structures to disconnect the initial channel structure covering the capacitor connection structures in the first direction.

In some implementations, removing the at least the portion of the initial channel structure covering the surfaces of the capacitor dielectric layer and the capacitor connection structures to disconnect the initial channel structure covering the capacitor connection structures in the first direction comprises: enabling the remained initial channel structure to cover the surfaces of the capacitor connection structures.

In some implementations, after removing the portion of the initial first dielectric layer corresponding to the end surface to expose the channel structures, the manufacturing method further comprises: forming bit lines connected with portions of the channel structures corresponding to the end surface, wherein the bit lines extend along the first direction.

In some implementations, a material of the channel structures comprises a metal oxide semiconductor.

In some implementations, forming the initial channel structure covering the first sidewall, the second sidewall, and the end surface comprises: forming the initial channel structure by a thin film deposition process.

According to at least one example of the present disclosure, by means of the semiconductor device, the memory system, and the manufacturing method of the semiconductor device provided in the present disclosure, the channel structure comprises the first side portion and the second side portion arranged along the first direction and the connection portion connected to the first end portions of the first side portion and the second side portion in the second direction, the first side portion and the second side portion respectively serve as channels of a transistor, such that a transistor structure can be more compact, thereby effectively reducing footprint, increasing storage density, and facilitating improvement of an iterative miniaturization capability of a feature size of the semiconductor device.

### BRIEF DESCRIPTION OF THE DRAWINGS

Other features, purposes and advantages of the present disclosure will become more apparent by reading the detailed description of non-limitative implementations made with reference to the following drawings. In the drawings:

FIGS. 1A and 1B are schematic structural diagrams of a semiconductor device provided by an example of the present disclosure;

FIG. 2 is a schematic structural diagram of a semiconductor device according to another example of the present disclosure;

FIG. 3 is a block diagram of a system having a memory system provided by an example of the present disclosure;

FIG. 4 is a flow diagram of a manufacturing method of a semiconductor device provided by an example of the present disclosure;

FIGS. 5A to 5K are schematic structural diagrams of a semiconductor device provided by an example of the present disclosure in a manufacturing process; and

FIGS. 6A to 6K are schematic structural diagrams of a semiconductor device provided by another example of the present disclosure in a manufacturing process.

### DETAILED DESCRIPTION

For better understanding of the present disclosure, various aspects of the present disclosure will be described in more detail with reference to the drawings. It is understood that these detailed descriptions are only descriptions of exemplary implementations of the present disclosure, and are not intended to limit the scope of the present disclosure in any manner. Like reference numbers refer to like elements throughout the specification. The expression “and/or” includes any or all combinations of one or more of listed associated items.

In the specification, the expressions, such as first, second, third and the like, are only used to distinguish one feature from another feature, instead of representing any limitation to the features, particularly instead of representing any sequential order. Thus, without departing from the teaching of the present disclosure, a first side portion discussed in the present disclosure may be also called a second side portion, or vice versa.

For case of illustration, the thicknesses, sizes and shapes of components have been slightly adjusted in the drawings. The drawings are merely exemplary and are not drawn to scale precisely. As used herein, terms, “approximately”, “about”, and the like, are used to represent approximation, instead of representing a degree, and are intended to describe inherent deviations in measured values or calculated values as recognized by those of ordinary skill in the art.

It should be also understood that expressions, such as “comprise”, “comprising”, “have”, “include”, and/or “including”, etc., are open-ended expressions, rather than close-ended expressions in the specification. They represent the existence of the stated features, elements and/or components, but the existence of one or more other features, elements, components and/or combinations thereof is not precluded. Moreover, the expression, such as “at least one of . . . ”, appearing before a list of listed features, modifies the whole list of features, rather than an individual element therein. Furthermore, “may” is used to represent “one or more implementations of the present disclosure” when describing the implementations of the present disclosure. Moreover, the term “exemplary” is intended to refer to an example or illustration.

Unless otherwise defined, all phrases (including engineering terms and technical terms) used herein have the same meanings as those generally understood by those of ordinary skill in the art to which the present disclosure pertains. It should be further understood that words as defined in common dictionaries should be interpreted as having a meaning that is consistent with their meaning in the context of the related art, and should not be interpreted in an idealized or overly formal sense unless otherwise stated expressly in the present disclosure.

Implementations and features in the implementations of the present disclosure may be combined with each other in the case of no conflicts. In addition, unless otherwise defined expressly or conflicting with the context, specific steps included in a method set forth in the present disclosure are not necessarily limited to the described order, but may be carried out in any order or in parallel.

Furthermore, “connected” or “joined”, when used in the present disclosure, may represent direct contact or indirect contact between respective components, unless otherwise expressly defined or derived from the context.

The present disclosure will be detailed below with reference to the figures and in conjunction with the examples.

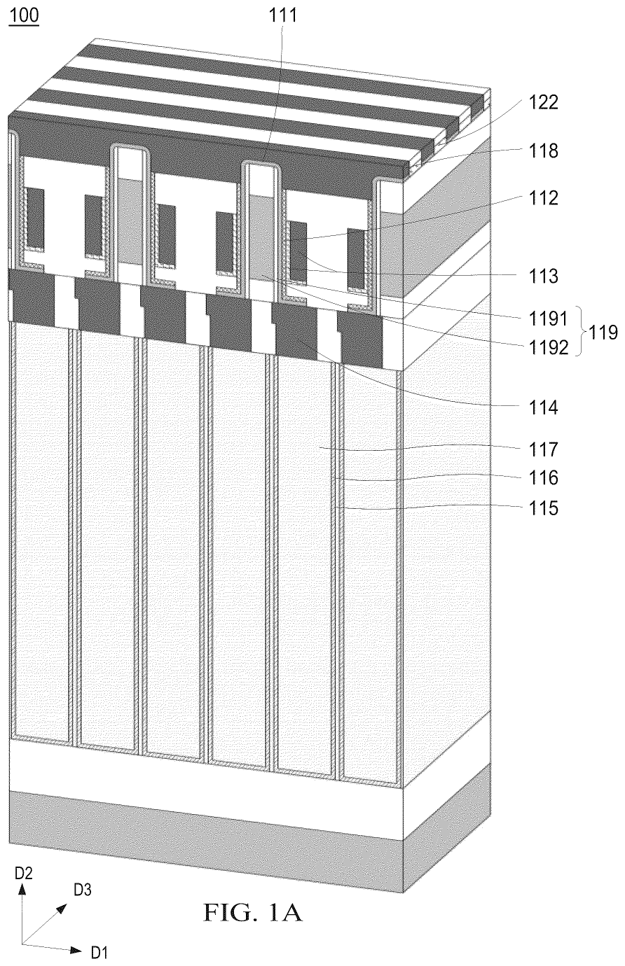

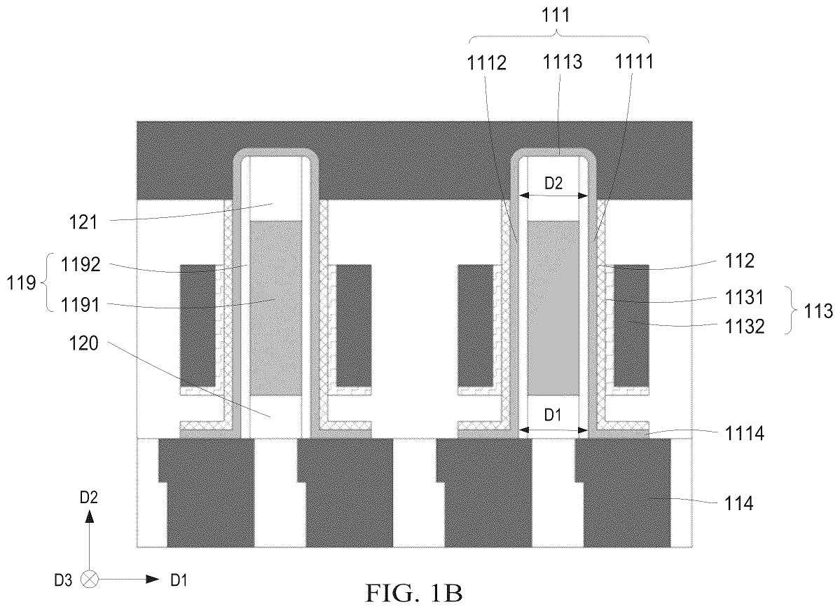

FIGS. 1A and 1B are schematic structural diagrams of a semiconductor device provided by an example of the present disclosure. FIG. 1A is a schematic perspective view of a semiconductor device 100. FIG. 1B is a schematic partial cross-sectional view of the semiconductor device 100. For example, the semiconductor device 100 may be a part of a dynamic random access memory (DRAM).

It should be pointed out that hereinafter, direction D1, direction D2, and direction D3 in each drawing show a spatial relationship of each component in the semiconductor device. For example, the direction D2 is a direction from a capacitor to a transistor, and the direction D1 and the direction D3 are two directions that intersect with (e.g., perpendicular to) each other on a plane intersecting with (e.g., perpendicular to) the direction D2. For example, the direction D1 is a bit line direction, and the direction D3 is a word line direction. The same concept will be adopted throughout the present disclosure to describe the spatial relationship of each component in the semiconductor device.

As shown in FIGS. 1A and 1B, the semiconductor device 100 comprises a channel structure 111. The channel structure 111 comprises a first side portion 1111, a second side portion 1112, and a connection portion 1113. The first side portion 1111 and the second side portion 1112 are arranged in the direction D1, and the connection portion 1113 is connected to first end portions of the first side portion 1111 and the second side portion 1112 in the direction D2.

In some implementations, the first side portion 1111 and the second side portion 1112 may respectively extend in a plane constituted by the direction D2 and the direction D3, wherein two ends of the first side portion 1111 and the second side portion 1112 in the direction D2 may respectively be the first end portion and a second end portion. Extending sizes of the first side portion 1111 and the second side portion 1112 in the direction D2 or the direction D3 may be greater than the sizes of the first side portion and the second side portion in the direction D1. For example, the first side portion 1111 and the second side portion 1112 may have substantially the same size (e.g., an error is less than ±10%), and viewing from the direction D1, the first side portion 1111 overlaps with the second side portion 1112. The first side portion 1111 and the second side portion 1112 may be substantially plate-like. For example, the sizes of the first side portion 1111 and the second side portion 1112 in the direction D1 may be 3-10 nm, respectively.

In some implementations, the connection portion 1113 may extend in a plane constituted by the direction D1 and the direction D3, and extending sizes of the connection portion 1113 in the direction D1 and the direction D3 may be greater than a size of the connection portion in the direction D2. The connection portion 1113 may be substantially plate-like. For example, the size of the connection portion 1113 in the direction D3 may be the same as the sizes of the first side portion 1111 and the second side portion 1112 in the direction D3; the size of the connection portion 1113 in the direction D1 may be a spacing distance between the first side portion 1111 and the second side portion 1112 in the direction D1; and a size of the connection portion 1113 in the direction D2 may be the same as the sizes of the first side portion 1111 and the second side portion 1112 respectively in the direction D1. For example, viewing from the direction D3, the first side portion 1111, the second side portion 1112, and the connection portion 1113 may be substantially in an inverted-U shape, and the connection portion 1113 may serve as a closed end of an inverted-U-shaped structure.

In some implementations, the channel structure 111 may further comprise extending portions 1114 located on the second end portions. The extending portions 1114 respectively extend along the direction D1 and directions facing away from the first side portion 1111 and the second side portion 1112. For example, the extending portion 1114 may be substantially parallel to the connection portion 1113. An extending size of the extending portion 1114 in the direction D3 may be the same as the extending sizes of the first side portion 1111, the second side portion 1112, and the connection portion 1113 respectively in the direction D3; and a size of the extending portion 1114 in the direction D2 may be the same as the size of the connection portion 1113 in the direction D2 and the sizes of the first side portion 1111 and the second side portion 1112 respectively in the direction D1.

In some implementations, along a direction opposite to the second direction D2, a spacing distance between the first side portion 1111 and the second side portion 1112 in the first direction D1 gradually increases. For example, at a position close to the connection portion 1113, a spacing distance d2 between the first side portion 1111 and the second side portion 1112 in the first direction D1 may be less than a spacing distance d1 between the first side portion 1111 and the second side portion 1112 in the first direction D1 at a position far away from the connection portion 1113.

In some implementations, the first side portion 1111, the second side portion 1112, and the connection portion 1113 are of an integral structure. For example, the first side portion 1111, the second side portion 1112, and the connection portion 1113 (i.e., the channel structure 111) may be formed by means of the same process (e.g., a thin film deposition process). A particular formation method of the channel structure 111 will be described in detail below. For example, when materials of the first side portion 1111, the second side portion 1112, and the connection portion 1113 are the same, there is no distinct boundary among the first side portion, the second side portion, and the connection portion. In an example, the materials of the first side portion 1111, the second side portion 1112, and the connection portion 1113 (i.e., the channel structure 111) may comprise one or more of semiconductor materials such as polycrystalline silicon (Poly-Si), amorphous silicon (α-Si), a metal oxide semiconductor (for example, indium gallium zinc oxide (IGZO), zinc oxide (ZnO), indium tin oxide (ITO)), etc. When the material of the channel structure 111 is the metal oxide semiconductor (e.g., the indium gallium zinc oxide (IGZO)), leakage current of a channel may be significantly reduced, data retention characteristic is improved, and better sense margin can also be achieved. In an example, the extending portion 1114, as a part of the channel structure 111, may have the same material as the materials of the first side portion 1111, the second side portion 1112, and the connection portion 1113.

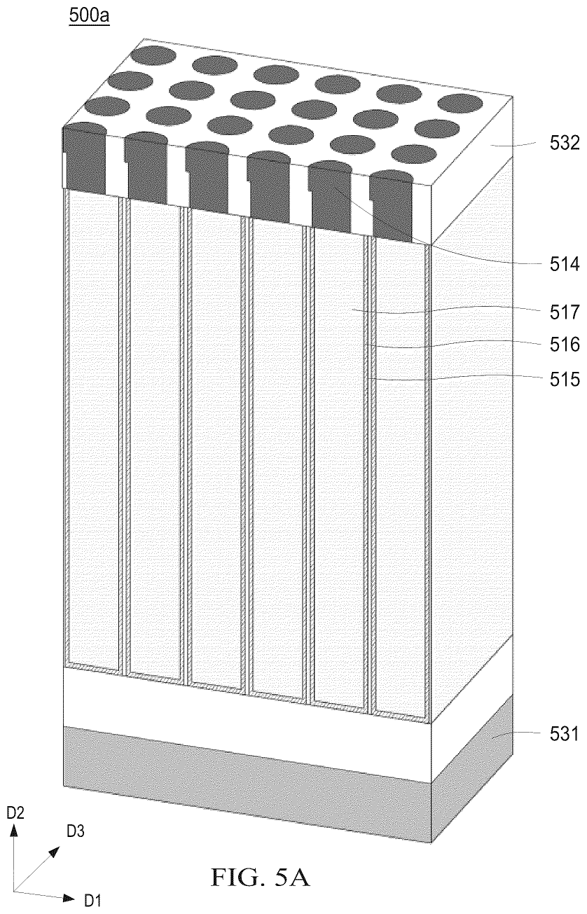

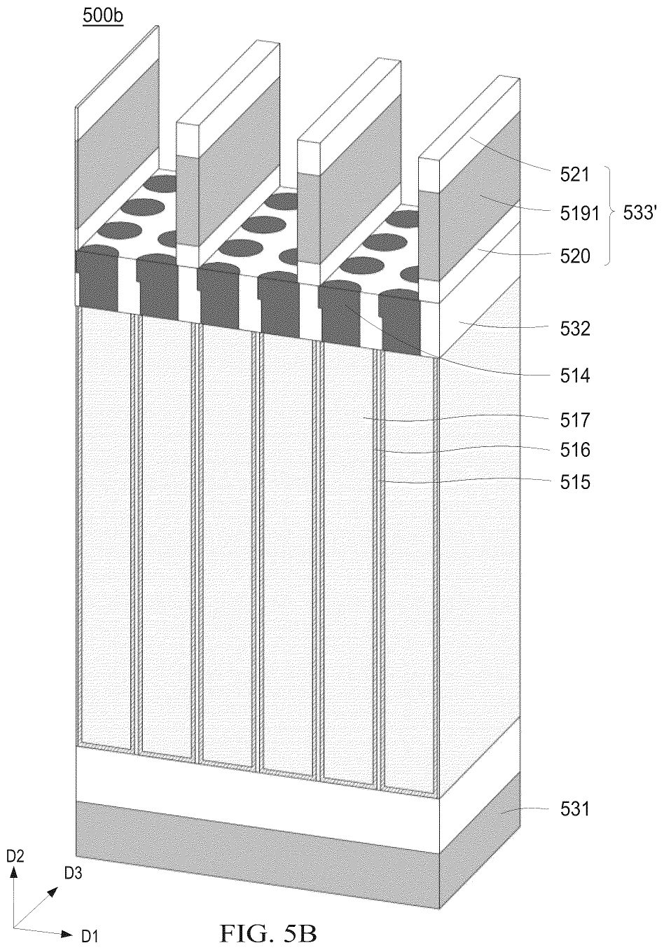

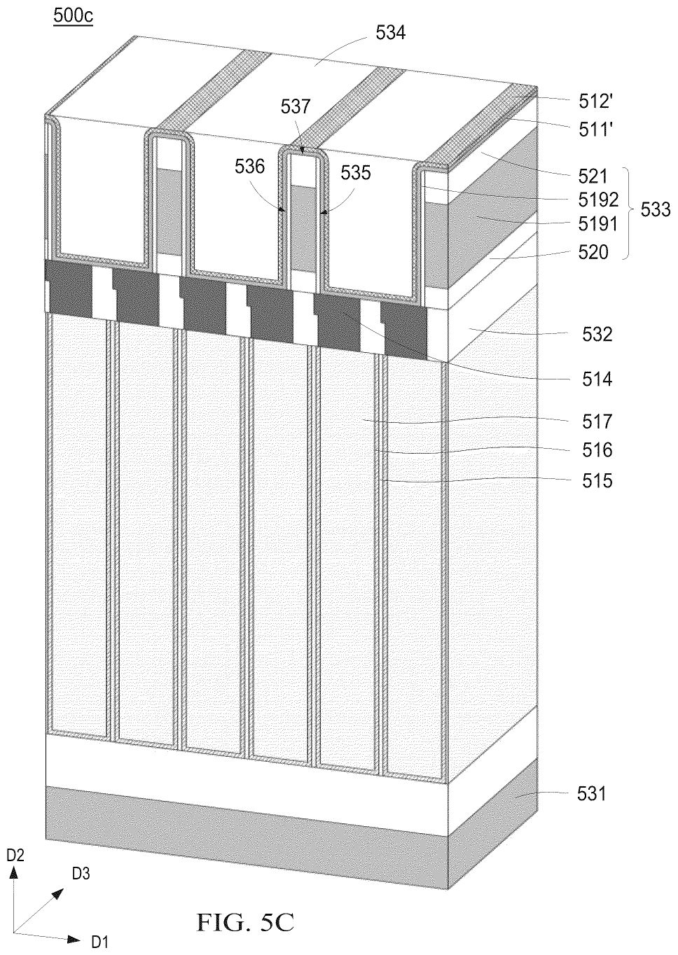

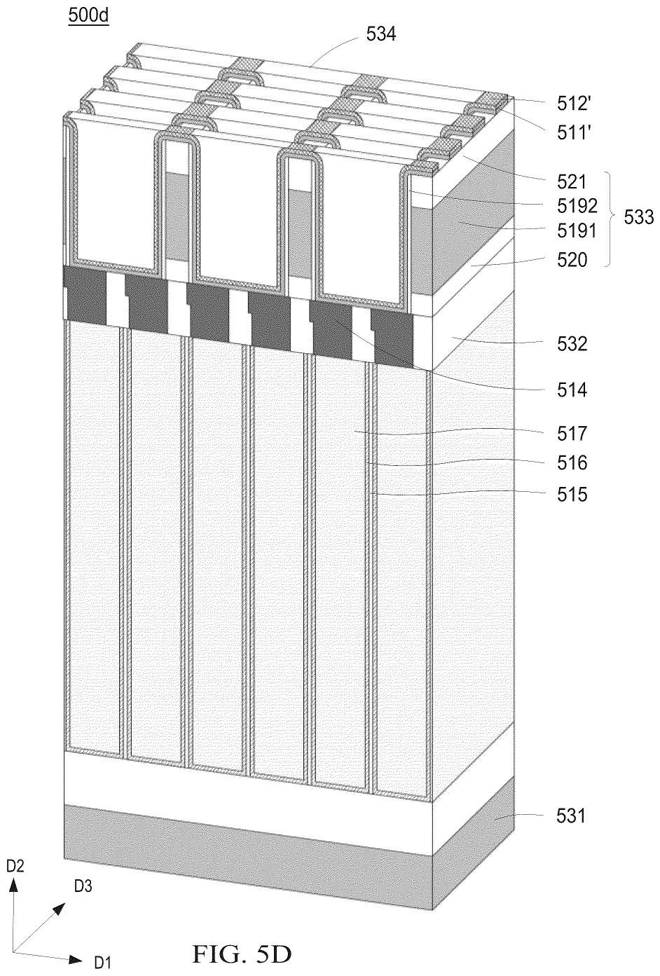

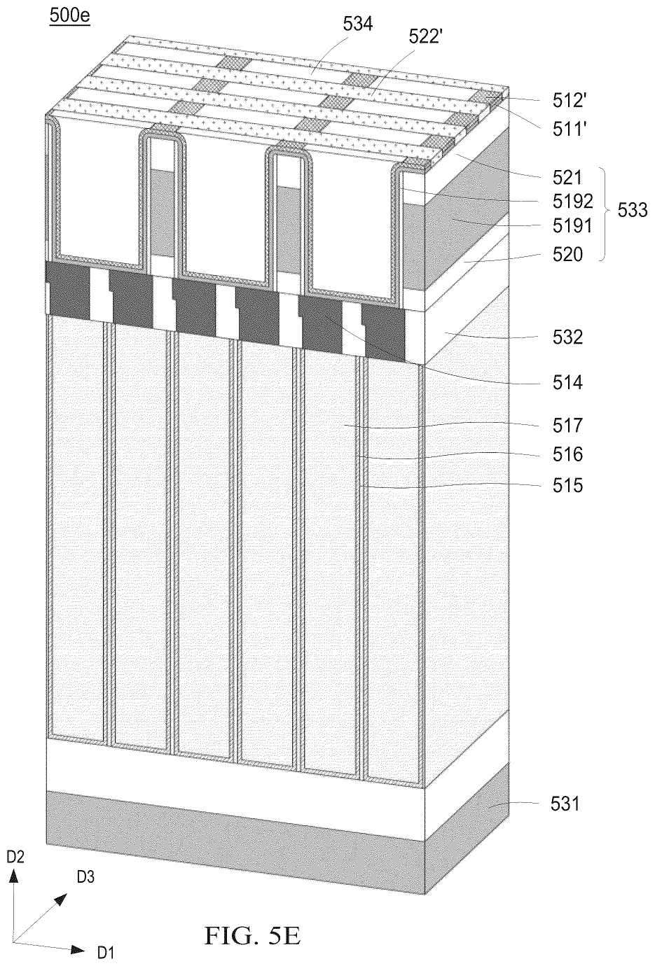

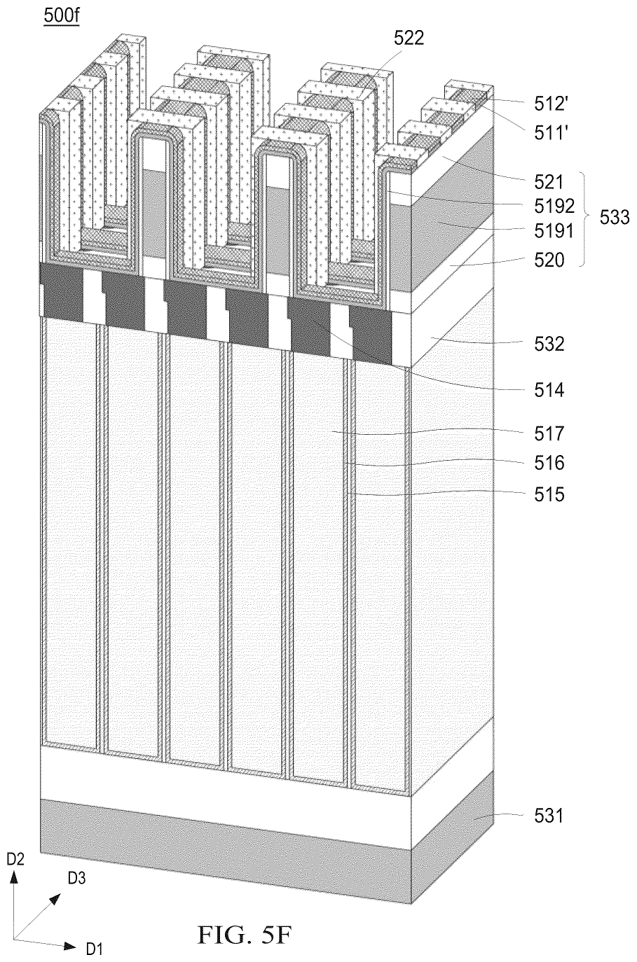

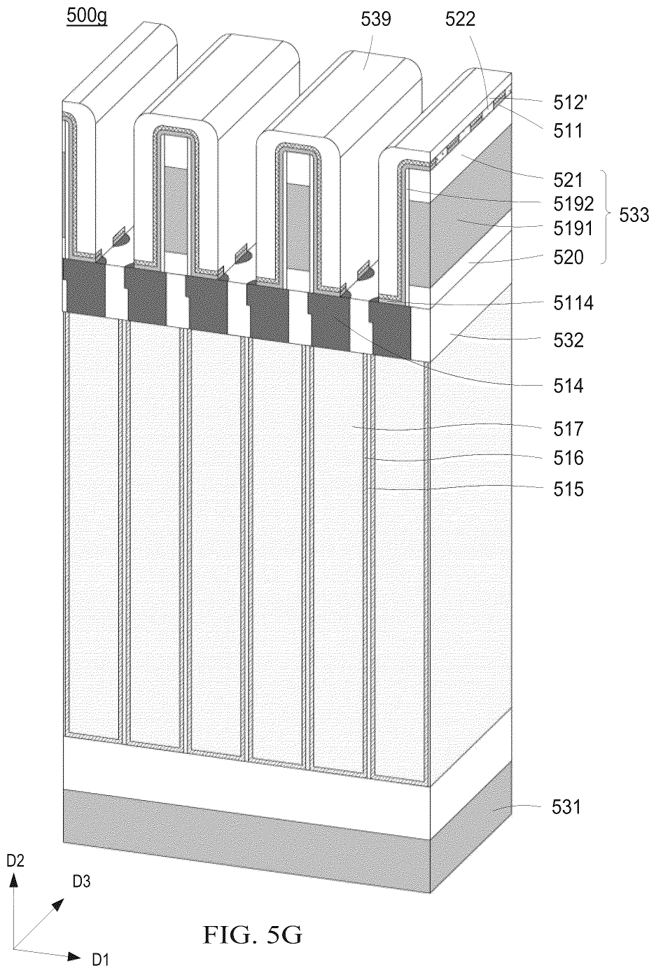

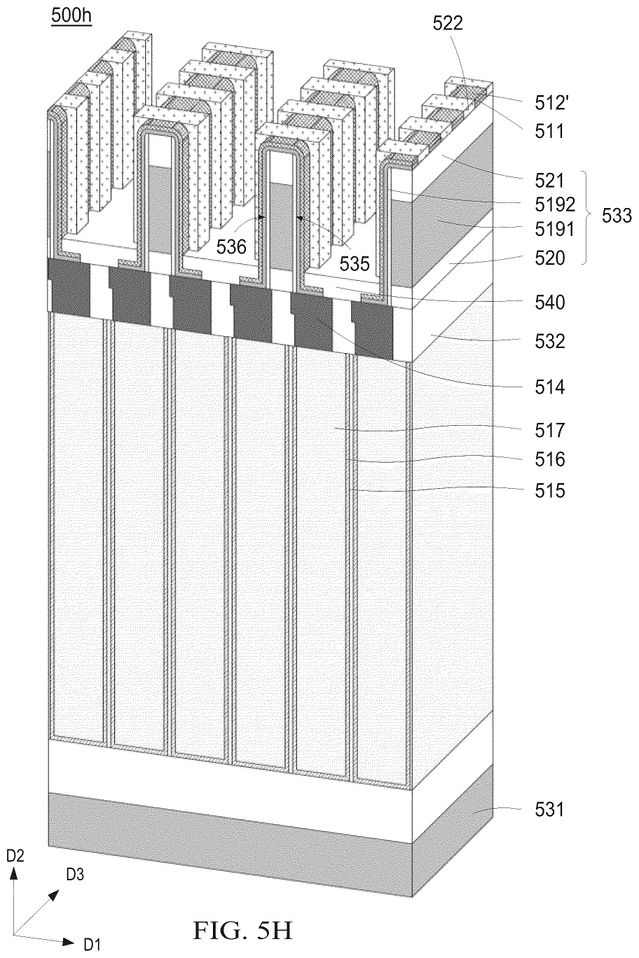

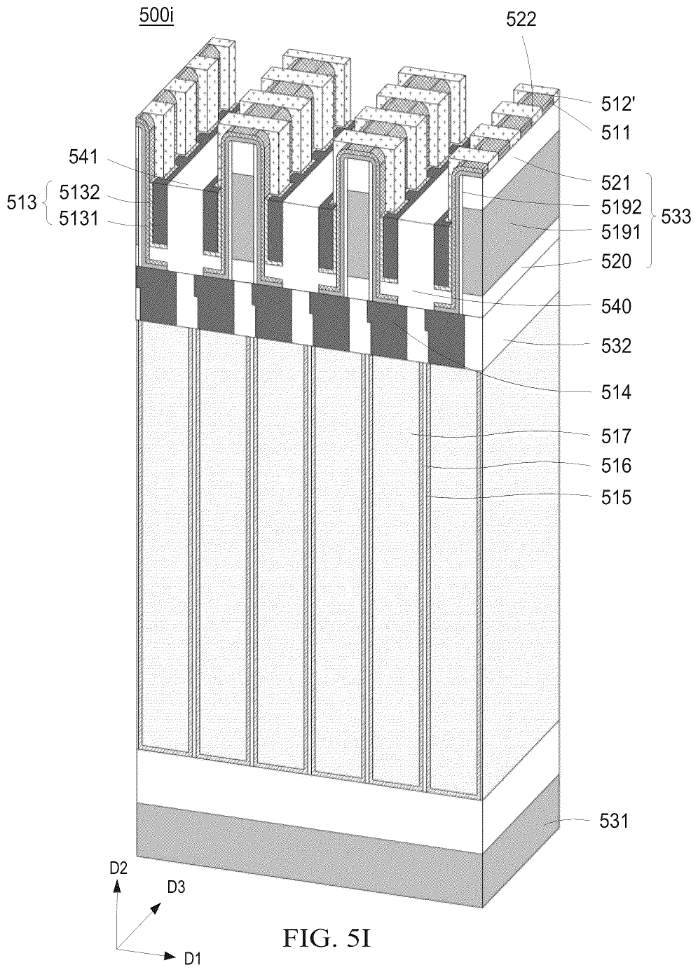

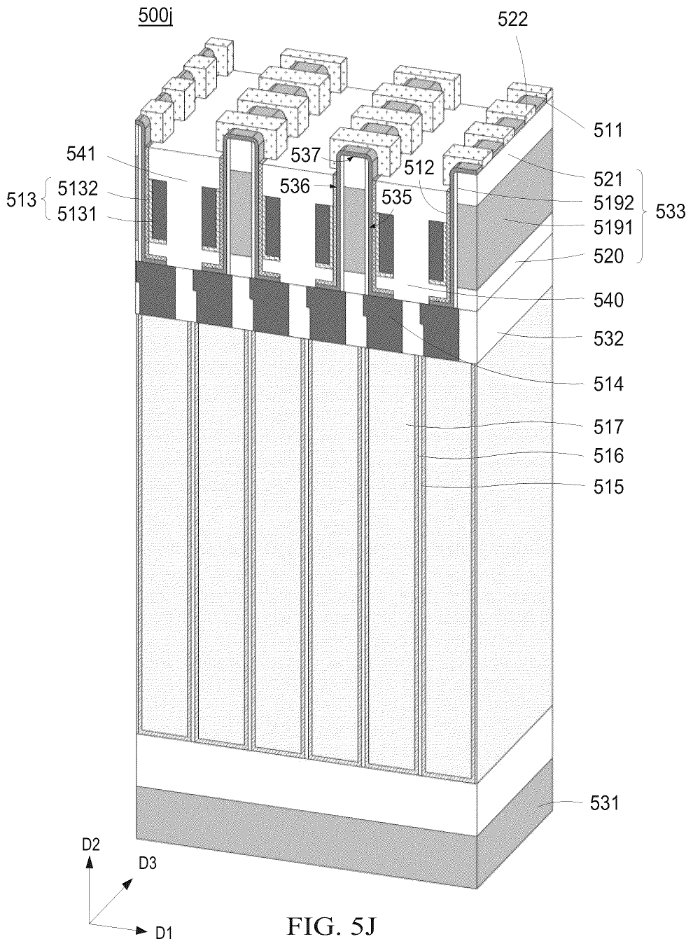

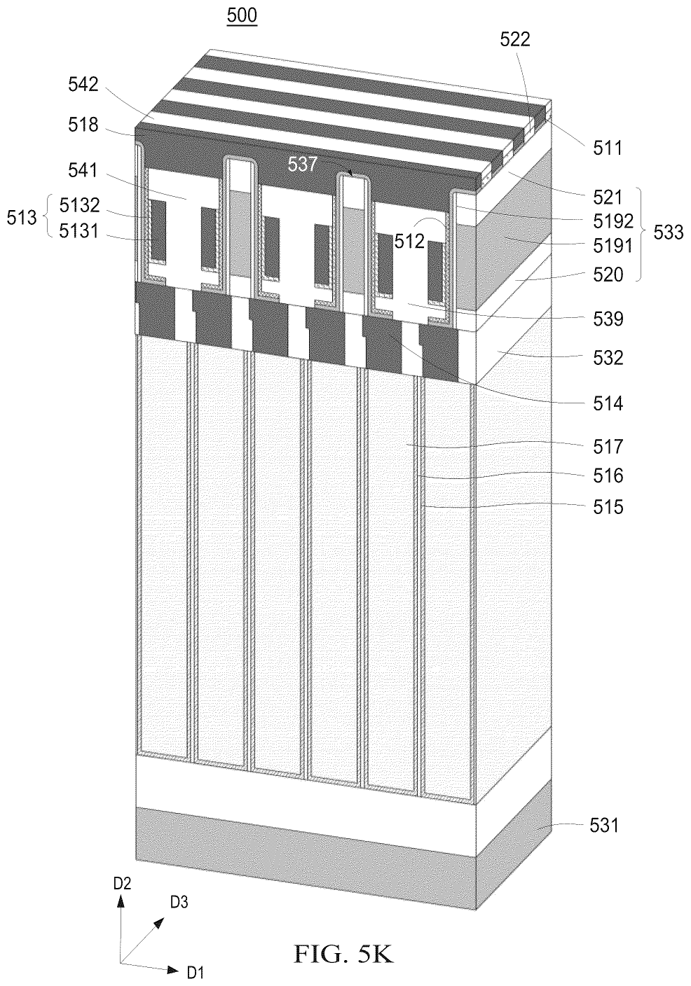

In some implementations, a plurality of channel structures 111 may be arranged in an array in the direction D1 and the direction D2. In an example, the channel structures 111 may be arranged as being spaced apart in the direction D1, and the connection portions 1113 in the individual channel structures 111 are not connected with each other. In an example, the channel structures 111 may also be arranged as being spaced apart in the direction D3. The semiconductor device 100 may further comprise a third isolation structure 122 (e.g., a third isolation structure 522 shown in FIG. 5F). The third isolation structure 122 may be located between adjacent channel structures 111 in the direction D3. For example, viewing from the direction D3, each third isolation structure 122 may be substantially in an inverted-U shape. A size of the third isolation structure 122 in the direction D1 may be greater than a size of the channel structure 111 in the direction D1. For example, a material of the third isolation structure 122 may comprise silicon nitride (Si3N4). Continuously referring to FIGS. 1A and 1B, the semiconductor device 100 further comprises first dielectric layers 112 located on surfaces of the first side portion 1111 and the second side portion 1112 opposite to each other. In some implementations, the first dielectric layer 112 may extend in the plane constituted by the direction D2 and the direction D3. For example, the first dielectric layer 112 has the same size as the first side portion 1111 and the second side portion 1112 in the direction D3. In the direction D2, the size of the first dielectric layer 112 is less than the sizes of the first side portion 1111 and the second side portion 1112. In an example, a material of the first dielectric layer 112 may comprise one or more of silicon oxide (SiO2), silicon nitride (Si3N4), silicon oxynitride (SiOxNy), a high dielectric constant material or any other suitable insulation materials. For example, the material of the first dielectric layer 112 may comprise the high dielectric constant material such as aluminum oxide (A12O3), zirconium oxide (ZrO2), hafnium oxide (HfO2), etc.

The semiconductor device 100 further comprises a gate layer 113. The gate layer 113 is located on a surface of the first dielectric layer 112, and extends (e.g., continuously extends) along the direction D3. For example, the gate layers 113 may be located on the surfaces of the first dielectric layers 112 of a column of the channel structures 111 arranged along the direction D3. In some examples, the gate layer 113 may comprise a first adhesion layer 1131 and a metal layer 1132, which are attached to each other. The first adhesion layer 1131 is in direct contact with the first dielectric layer 112, and extends to an end surface of the metal layer 1132 close to a capacitor connection structure 114. The capacitor connection structure 114 will be described in detail below. For example, viewing from the direction D3, the first adhesion layer 1131 may be substantially in an L shape, and a portion of the first adhesion layer 1131 that extends to the end surface of the metal layer 1132 is closer to the second end portions of the first side portion 1111 and the second side portion 1112. A portion of the first adhesion layer 1131 is located between the metal layer 1132 and the first dielectric layer 112, so as to facilitate improvement of binding performance between the metal layer 1132 and the first dielectric layer 112. In an example, a material of the first adhesion layer 1131 may comprise one or more of titanium (Ti), titanium nitride (TiN), tantalum (Ta), tantalum nitride (TaN) or any other suitable materials. A material of the metal layer 1132 may comprise one or more of tungsten (W), molybdenum (Mo), copper (Cu), aluminum (Al), ruthenium (Ru), titanium (Ti) or any other suitable metal materials. In some other examples, the gate layer 113 may not have a composite structure but is composed of a conductive material, to which the present disclosure imposes no specific limitations.

In some implementations, on a plane perpendicular to the direction D2, surfaces of the gate layer 113 (e.g., a gate layer 513 shown in FIG. 5I) close to the first side portion 1111 and the second side portion 1112 are concavo-convex-shaped. For example, viewing from the direction D2, the surfaces of the gate layer 113 in contact with the first dielectric layer 112 and the third isolation structure 122 are concavo-convex-shaped, wherein the surface of the gate layer 113 in contact with the first dielectric layer 112 protrudes, and the surface of the gate layer 113 in contact with the third isolation structure 122 depresses. Since the third isolation structure 122 is located between adjacent channel structures 111 in the direction D3, the gate layer 113 has concavo-convex-shaped surfaces.

Based on the above, in some implementations, portions of the first side portion 1111 (or the second side portion 1112), the first dielectric layer 112, and the gate layer 113 corresponding to the first side portion 1111 (or the second side portion 1112) may constitute a transistor. In the transistor, the first side portion 1111 (or the second side portion 1112) may serve as a channel, the portion of the gate layer 113 corresponding to the first side portion 1111 (or the second side portion 1112) may serve as a gate, and two ends (i.e., the first end portion and the second end portion) of the first side portion 1111 (or the second side portion 1112) may respectively serve as one of a source and a drain. Two transistors respectively comprising the first side portion 1111 and the second side portion 1112 may be distributed in a mirror image manner relative to the connection portion 1113. The gate layer 113 extending in the direction D3 may be configured to control a column of the transistors arranged along the direction D3. Each transistor may be a part of a DRAM memory cell.

According to the semiconductor device provided by the above-mentioned examples of the present disclosure, the channel structure comprises the first side portion and the second side portion arranged along the first direction, and the connection portion connected to first end portions of the first side portion and the second side portion in the second direction, wherein the first side portion and the second side portion respectively serve as channels of a transistor, such that a transistor structure can be more compact, thereby effectively reducing footprint, increasing storage density, facilitating improvement of an iterative miniaturization capability of a feature size of the semiconductor device.

In some implementations, the semiconductor device 100 may further comprise the capacitor connection structures 114. The capacitor connection structures 114 may be respectively connected to the second end portions of the first side portion 1111 and the second side portion 1112. That is to say, the second end portion of the first side portion 1111 is connected with one capacitor connection structure 114, and the second end portion of the second side portion 1112 is connected with the other capacitor connection structure 114. The two capacitor connection structures 114 are electrically isolated from each other. For example, the capacitor connection structure 114 may be substantially pillar-shaped. In an example, a material of the capacitor connection structure 114 may comprise one or more of tungsten (W), molybdenum (Mo), copper (Cu), aluminum (Al), ruthenium (Ru), titanium (Ti), titanium nitride (TiN), polycrystalline silicon (Poly-Si), indium tin oxide (ITO), metal silicide (e.g., titanium silicide (TiSi2), cobalt silicide (CoSi2), and nickel platinum silicide (NiPtSi)) or any other suitable conductive materials. In an example, when the channel structure 111 has the extending portion 1114, the extending portion 1114 may be in direct contact with the capacitor connection structure 114 to increase a contact area between the extending portion and the capacitor connection structure, such that transmission efficiency is improved, and the reliability of an electrical connection is guaranteed.

In some implementations, the semiconductor device 100 may further comprise an outer electrode layer 115, an insulation layer 116, and an inner electrode 117. The outer electrode layer 115 is disposed on a side of the capacitor connection structure 114 facing away from the channel structure 111. The inner electrode 117 is located in the outer electrode layer 115, and is connected (e.g., in direct contact) with the capacitor connection structure 114. For example, the inner electrode 117 may be substantially a pillar-shaped structure, and at least partially penetrate through the outer electrode layer 115. Along the direction opposite to the direction D2, a size (e.g., a diameter) of the inner electrode 117 on a plane perpendicular to the direction D2 gradually reduces. The insulation layer 116 is located between the outer electrode layer 115 and the inner electrode 117. For example, the insulation layer 116 may be substantially a barrel-shaped structure with an opening on one end; the inner electrode 117 is located in the insulation layer 116; and the opening end of the insulation layer 116 faces towards the capacitor connection structure 114 such that the inner electrode 117 is in direct contact with the capacitor connection structure 114. In an example, materials of the outer electrode layer 115 and the inner electrode 117 may comprise one or more of tungsten (W), molybdenum (Mo), copper (Cu), aluminum (Al), ruthenium (Ru), titanium (Ti), titanium nitride (TiN), polycrystalline silicon (Poly-Si), indium tin oxide (ITO), or any other suitable conductive materials. A material of the insulation layer 116 may comprise one or more of silicon oxide (SiO2), silicon nitride (Si3N4), silicon oxynitride (SiOxNy) or any other suitable insulation materials.

Based on the above, in some implementations, the inner electrode 117, the insulation layer 116, and the outer electrode layer 115 may constitute a capacitor. An electrode (e.g., the inner electrode 117) of the capacitor is connected with one (e.g., the second end portion of the first side portion 1111 or the second side portion 1112) of the source or the drain of the transistor by means of the capacitor connection structure 114. The transistor and the capacitor may constitute a memory cell (for example, a DRAM memory cell). The other electrodes (e.g., the outer electrode layers 115) of the plurality of capacitors may be connected with each other.

The capacitor may also be implemented in other structural type, for example, the capacitor may be constituted by a conductive layer, an insulation layer, and a conductive layer (not shown) successively stacking in the direction D2. The present disclosure does not particularly limit the structure of the capacitor, and the capacitor may be implemented as any structural type known in the art.

In some implementations, the semiconductor device 100 may further comprise a bit line 118. The bit line 118 extends along the direction D1, and is connected (e.g., in direct contact) with the connection portion 1113. The bit line 118 may be connected with each connection portion 1113 in a row of the channel structures 111 arranged along D1. Therefore, one of the source or the drain of each transistor in a row of the transistors arranged along the direction D1 is connected with the same bit line 118. The number of the bit lines 118 may be plural, and the plurality of bit lines 118 may be arranged along the direction D3. In an example, a material of the bit line 118 may comprise one or more of tungsten (W), molybdenum (Mo), copper (Cu), aluminum (Al), ruthenium (Ru), titanium (Ti), titanium nitride (TiN), polycrystalline silicon (Poly-Si), indium tin oxide (ITO), or any other suitable conductive materials.

In some implementations, the semiconductor device 100 may further comprise a shielding structure 119. The shielding structure 119 may be located between the first side portion 1111 and the second side portion 1112; and the shielding structure 119 may comprise a conductive structure 1191 and a second dielectric layer 1192. The conductive structure 1191 may extend (e.g., continuously extend) along the direction D3. The second dielectric layers 1192 may be located between the conductive structure 1191 and the first side portion 1111, and located between the conductive structure 1191 and the second side portion 1112. For example, along the direction opposite to the direction D2, a size of the conductive structure 1191 in the direction D1 gradually increases. For another example, the second dielectric layer 1192 may extend (e.g., continuously extend) along the direction D3; and two second dielectric layers 1192 may respectively located on two sidewalls of the conductive structure 1191 in the direction D1, and respectively in direct contact with the first side portion 1111 and the second side portion 1112. In an example, a material of the conductive structure 1191 may comprise one or more of tungsten (W), molybdenum (Mo), copper (Cu), aluminum (Al), ruthenium (Ru), titanium (Ti), titanium nitride (TiN), amorphous silicon (α-Si), polycrystalline silicon (Poly-Si), indium tin oxide (ITO) or any other suitable conductive materials; and a material of the second dielectric layer 1192 may comprise one or more of silicon oxide (SiO2), silicon nitride (Si3N4), silicon oxynitride (SiOxNy), a high dielectric constant material or any other suitable insulation materials. For example, the conductive structure 1191 may be prepared by employing doped polycrystalline silicon (Poly-Si) or doped amorphous silicon (α-Si). The shielding structure 119 may be located on a back side (a side not disposed with a gate) of the channel of the transistor, for example, a voltage (e.g., a ground voltage) is applied to the shielding structure 119 to improve a coupling effect between adjacent transistors, and also to facilitate reduction of off-state current Ioff and sub-threshold voltage swing of the transistor, and to adjusting a threshold voltage Vt of the transistor, such that the electrical performance of the transistor is fully optimized.

In some implementations, the semiconductor device 100 may further comprise a first isolation structure 120 and a second isolation structure 121. The first isolation structure 120 is located between the first side portion 1111 and the second side portion 1112, and located on a side of the conductive structure 1191 facing away from the connection portion 1113. The second isolation structure 121 is located between the connection portion 1113 and the conductive structure 1191, and located on a side of the conductive structure 1191 close to the connection portion 1113. For example, in the direction D2, a size of the second dielectric layer 1192 may be greater than a size of the conductive structure 1191; and the first isolation structure 120 may be located in a space enclosed by the second dielectric layer 1192 and the conductive structure 1191, a surface of the first isolation structure facing away from the connection portion 1113 is substantially flush with a surface of the extending portion 1114 facing away from the connection portion 1113 (e.g., an error is less than +10%). The second isolation structures 121 may be located in a space enclosed by the second dielectric layer 1192, the conductive structure 1191, and the connection portion 1113. In an example, a material of the first isolation structure 120 may comprise one or more of silicon oxide (SiO2), silicon nitride (Si3N4), silicon oxynitride (SiOxNy) or any other suitable insulation materials. A material of the second isolation structure 121 may comprise a non-silicon oxide material. In other words, the second isolation structure 121 may be prepared by employing a material with an etching selection ratio different from the silicon oxide (SiO2) relative to the same etching material. For example, the material of the second isolation structure 121 may comprise silicon nitride (Si3N4). The first isolation structure 120 and the second isolation structure 121 may be configured to adjust a size of the conductive structure 1191 in the direction D2, so as to match a size of the gate layer 113 in the direction D2. In addition, the second isolation structure 121 may further be configured to electrically isolate the conductive structure 1191 and the connection portion 1113.

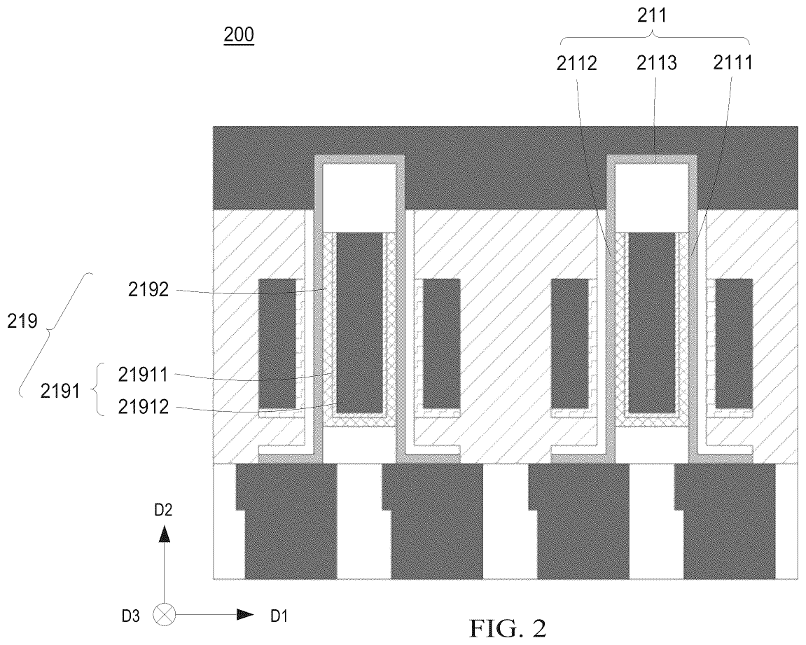

FIG. 2 is a schematic structural diagram of a semiconductor device according to another example of the present disclosure. Part of components of the semiconductor device 200 are omitted in FIG. 2. For the purpose of concise description, content same as that in the previous example is not repeatedly described here in the present disclosure.

As shown in FIG. 2, in the semiconductor device 200, the shielding structure 219 may be located between the first side portion 2111 and the second side portion 1112; and the shielding structure 219 may comprise a conductive structure 2191 and a second dielectric layer 2192. The conductive structure 2191 may extend (e.g., continuously extend) along the direction D3. The second dielectric layers 2192 may be located between the conductive structure 2191 and the first side portion 2111, and located between the conductive structure 2191 and the second side portion 2112; and the second dielectric layer 2192 may also be located on an end surface of the conductive structure 2191 facing away from a connection portion 2113. For example, viewing from the direction D3, the second dielectric layer 2192 may be substantially in a U shape, and extend (e.g., continuously extend) along the direction D3. The conductive structure 2191 is located in a space enclosed by the second dielectric layer 2192, a surface of the conductive structure close to the connection portion 2113 is substantially flush with a surface of the second dielectric layer 2192 close to the connection portion 2113 (e.g., an error is less than ±10%). In an example, the conductive structure 2191 may comprise a second adhesion layer 21911 and a metal structure 21912. For example, viewing from the direction D3, the second adhesion layer 21911 may be substantially in a U shape, and the metal structure 21912 may be located in a space enclosed by the second adhesion layer 21911. In an example, a material of the second adhesion layer 21911 may comprise one or more of titanium (Ti), titanium nitride (TiN), tantalum (Ta), tantalum nitride (TaN) or any other suitable materials. For example, a material of the metal structure 21912 may comprise one or more of tungsten (W), molybdenum (Mo), copper (Cu), aluminum (Al), ruthenium (Ru), titanium (Ti) or any other suitable metal materials. The second adhesion layer 21911 facilitates improvement of binding performance between the metal structure 21912 and the second dielectric layer 2192. As an alternative, the conductive structure 2191 may not have a composite structure but is composed of a conductive material, to which the present disclosure imposes no specific limitations.

Although the shielding structure 119 or 219 is described in detail above, a space enclosed by the channel structure may be filled with one or more insulation materials, so as to electrically isolate the first side portion 1111 or 2111 and the second side portion 1112 or 2112, to which the present disclosure imposes no specific limitations.

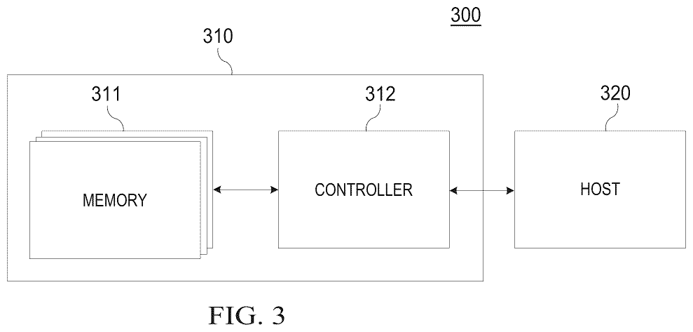

An example of the present disclosure further provides a memory system. FIG. 3 is a block diagram of a system having a memory system provided by an example of the present disclosure.

As shown in FIG. 3, the system 300 may be a mobile phone, a desktop computer, a laptop computer, a tablet computer, a vehicle computer, a gaming console, a printer, a positioning device, a wearable electronic device, a smart sensor, a virtual reality (VR) device, an augment reality (AR) device, or any other suitable electronic devices (which have a memory system 310 located therein). As shown in FIG. 3, the system 300 may comprise a host 320 and the memory system 310. The memory system 310 has one or more memories 311 and a controller 312. The host 320 may be a processor of an electronic device, such as a central processing unit (CPU), or may be a system-on-chip (SoC), such as an disclosure processor (AP). The host 320 may be configured to send or receive data to or from the memories 311.

In some implementations, the controller 312 is coupled to the memories 311 and the host 320, and is configured to control the memories 311. For example, the controller 312 may be configured to control the memories 311 to execute operations such as reading, erasing, and programming. The controller 312 may also manage data stored in the memories 311, and communicate with the host 320. For example, the controller 312 may communicate with an external device (e.g., the host 320) according to a particular communication protocol.

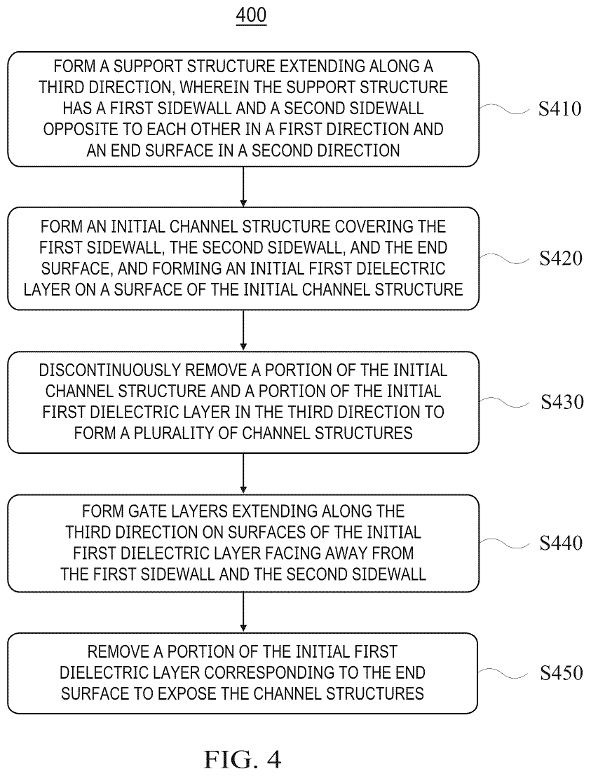

Examples of the present disclosure further provide a manufacturing method of a semiconductor device. FIG. 4 is a flow diagram of a manufacturing method of a semiconductor device provided by an example of the present disclosure. As shown in FIG. 4, the manufacturing method 400 of the semiconductor device (hereinafter simply called as the manufacturing method 400) may comprise the following operations.

S410, a support structure extending along a third direction is formed, wherein the support structure has a first sidewall and a second sidewall, which are opposite to each other in a first direction, and an end surface in a second direction.

S420, an initial channel structure covering the first sidewall, the second sidewall, and the end surface is formed, and an initial first dielectric layer is formed on a surface of the initial channel structure.

S430, a portion of the initial channel structure and a portion of the initial first dielectric layer are discontinuously removed in the third direction to form a plurality of channel structures.

S440, a gate layer extending along the third direction is formed on a surface of the initial first dielectric layer facing away from the first sidewall and the second sidewall.

S450, a portion of the initial first dielectric layer corresponding to the end surface is removed to expose the channel structure.

According to the manufacturing method of the semiconductor device provided by this example, first, the initial channel structure covering the first sidewall, second sidewall, and end surface of the support structure is formed, and the initial first dielectric layer is formed on the surface of the initial channel structure. Next, a portion of the initial channel structure and a portion of the initial first dielectric layer are discontinuously removed in the third direction to form the plurality of channel structures, wherein a portion of the channel structure covering the first sidewall and the second sidewall may serve as channel of a transistor, such that a transistor structure can be more compact, thereby effectively reducing footprint, increasing storage density, and facilitating improvement of an iterative miniaturization capability of a feature size of the semiconductor device.

FIGS. 5A to 5K are schematic structural diagrams of a semiconductor device provided by an example of the present disclosure in a manufacturing process. For example, each intermediate structure of the semiconductor device in this example in the manufacturing process may be formed according to the manufacturing method shown in FIG. 4, and is configured to form the semiconductor device 100 shown in FIGS. 1A and 1B. The above-mentioned operations S410 to S450 are described below in conjunction with FIGS. 5A to 5K and FIG. 4.

### S410

FIG. 5A shows an intermediate structure 500a comprising a substrate 531, an outer electrode layer 515, an insulation layer 516, an inner electrode 517, a capacitor dielectric layer 532, and a capacitor connection structure 514.

In some implementations, before a support structure 533 (referring to FIG. 5C) is formed, the manufacturing method 400 may further comprise the following operations. First, as shown in FIG. 5A, the outer electrode layer 515 may be formed on a side of the substrate 531 by employing a thin film deposition process such as chemical vapor deposition (CVD), physical vapor deposition (PVD), atomic layer deposition (ALD), or any combination thereof. For example, a material of the substrate 531 may comprise silicon (Si), germanium (Ge), gallium arsenide (GaAs), or indium phosphide (InP). For another example, the substrate 531 may be a silicon on insulator (SOI) or germanium on insulator (GeOI) substrate, or the like. Next, a via (not shown, the via corresponding to an outer contour of the insulation layer 516) penetrating through the outer electrode layer 515 may be formed by employing a lithography or etching (e.g., dry etching and/or wet etching) process. Then, the insulation layer 516 may be formed on an inner wall of the via by employing the thin film deposition process such as CVD, PVD, ALD, or any combination thereof, and the inner electrode 517 is formed in the insulation layer 516. For example, there may be a plurality of vias, which are arranged in an array in a direction D1 and a direction D3. As described above, one inner electrode 517, one insulation layer 516, and a portion of the outer electrode layer 515 at a periphery of the insulation layer 516 may constitute a capacitor. It should also be noted that since the via is formed by etching along a direction (e.g., a direction facing towards the substrate 531) opposite to a direction D2, sizes (e.g., diameters) of the via and the inner electrode 517 in the via on a plane perpendicular to the direction D2 gradually reduce along the direction opposite to the direction D2. Furthermore, any method known in the art may also be employed to form different structural types of capacitors.

In some implementations, first, a capacitor dielectric layer 532 covering a plurality of inner electrodes 517 and a plurality of insulation layers 516 may be formed by employing a thin film deposition process such as CVD, PVD, ALD, or any combination thereof. For example, the capacitor dielectric layer 532 may be formed on a side of the outer electrode layer 515 facing away from the substrate 531. A material of the capacitor dielectric layer 532 may comprise one or more of silicon oxide (SiO2), silicon nitride (Si3N4), silicon oxynitride (SiOxNy) or any other suitable insulation materials. Next, a plurality of capacitor connection structures 514 penetrating through the capacitor dielectric layer 532 and respectively connected with the plurality of inner electrodes 517 are formed by employing a lithography or etching (e.g., dry etching and/or wet etching) process and a thin film deposition process. For example, the capacitor connection structures 514 correspond to the inner electrodes 517 one to one.

FIG. 5B shows an intermediate structure 500b after a first isolation structure 520, a conductive structure 5191, and a second isolation structure 521 are formed. FIG. 5C shows an intermediate structure 500c after a second dielectric layer 5192, an initial channel structure 511′, an initial first dielectric layer 512′, and a first sacrificial layer 534 are formed.

In some implementations, as shown in FIG. 5B, the first isolation structure 520, the conductive structure 5191, and the second isolation structure 521, which are successively arranged along the direction D2, may be formed by employing a thin film deposition process such as CVD, PVD, ALD, or any combination thereof, and a lithography or etching (e.g., dry etching and/or wet etching) process. For example, the first isolation structure 520, the conductive structure 5191, and the second isolation structure 521 may be referred to as an initial support structure 533′. In an example, an operation of forming the initial support structure 533′ may comprise: first forming, by employing a thin film deposition process such as CVD, PVD, ALD, or any combination thereof, a composite layer formed by successively stacking respective materials of the first isolation structure 520, the conductive structure 5191, and the second isolation structure 521. Then, the composite layer may be patterned by employing a lithography or etching (for example, dry etching and/or wet etching) process to form a plurality of initial support structures 533′ arranged as being spaced apart along the direction D1. In an example, when a material of the conductive structure 5191 is polycrystalline silicon (Poly-Si) or amorphous silicon (α-Si), doping processing may be performed on the polycrystalline silicon (Poly-Si) or the amorphous silicon (α-Si), and doped elements may be activated by employing an annealing (e.g., laser annealing) process. Each initial support structure 533′ may extend (e.g., continuously extend) along the direction D3. For example, viewing from the direction D3, the initial support structure 533′ may be trapezoidal in shape. It should also be noted that since a trench between adjacent initial support structures 533′ is formed by etching along the direction (e.g., a direction facing towards the substrate 531) opposite to the direction D2, a size of the trench in the direction D1 gradually reduces and sizes of the remained initial support structures 533′ (or the conductive structures 5191) in the direction D1 gradually increase along the direction opposite to the direction D2. For another example, in a process of forming the initial support structure 533′, a layer (not shown) where the second isolation structure 521 is located may serve as a hard mask to prevent the conductive structure 5191 from being damaged.

Next, the second dielectric layers 5192 may be formed on sidewalls of the initial support structure 533′ opposite to each other in the direction D1 by employing a thin film deposition process such as CVD, PVD, ALD, or any combination thereof, as shown in FIG. 5C. In some examples, when the material of the conductive structure 5191 is the polycrystalline silicon (Poly-Si) or the amorphous silicon (α-Si), the second dielectric layers 5192 may be formed on sidewalls of the conductive structure 5191 opposite to each other in the direction D1 by employing an oxidation method (e.g., a dry-oxygen oxidation method and/or a wet-oxygen oxidation method). The first isolation structure 520, the second isolation structure 521, the conductive structure 5191, and the second dielectric layer 5192 may be referred to as an support structure 533. The support structure 533 may have a first sidewall 535 and a second sidewall 536, which are opposite to each other in the direction D1, and an end surface 537 in the direction D2. In addition, as described above, the conductive structure 5191 and the second dielectric layer 5192 may be referred to as a shielding structure to improve a coupling effect between adjacent transistors to be formed, so as to facilitate reduction of off-state current Ioff and sub-threshold voltage swing of the transistor, and to adjust a threshold voltage Vt of the transistor, such that the electrical performance of the transistor is fully optimized.

In some implementations, at least a portion of the support structure 533 may be located between adjacent capacitor connection structures 514 in the direction D1 by designing a spacing distance of the support structure 533 in the direction D1, and a size of each support structure 533 in the direction D1. For example, the adjacent capacitor connection structures 514 in the direction D1 are symmetrically arranged relative to the support structure 533. For another example, adjacent support structures 533 are spaced apart with two capacitor connection structures 514 in the direction D1.

### S420

Continuously referring to FIG. 5C, an initial channel structure 511′ covering the first sidewall 535, the second sidewall 536, and the end surface 537 may be formed by employing an thin film deposition process such as CVD, PVD, ALD, or any combination thereof. For example, a thickness of the initial channel structure 511′ relative to a surface covered by it may be 3-10 nm. Further, an initial first dielectric layer 512′ may be formed on a surface of the initial channel structure 511′ by employing a thin film deposition process such as CVD, PVD, ALD, or any combination thereof. The initial channel structure 511′ is formed by the thin film deposition process, and then a channel structure 511 (referring to FIG. 5G) is formed in a follow-up process, which is beneficial to reducing the difficulty of process control and providing a greater probability for iterative miniaturization of a feature size of the semiconductor device compared to an etching process.

In some implementations, when the adjacent support structures 533 are spaced apart with two capacitor connection structures 514, the initial channel structure 511′ may be formed on surfaces of the capacitor dielectric layer 532 and the capacitor connection structure 514.

In some implementations, the first sacrificial layer 534 may be filled between the adjacent support structures 533 formed with the initial channel structure 511′ and the initial first dielectric layer 512′ by employing a thin film deposition process such as CVD, PVD, ALD, or any combination thereof. A material of the first sacrificial layer 534 may be different from a material of the initial first dielectric layer 512′. For example, the material of the initial first dielectric layer 512′ may comprise a high dielectric constant material, and the material of the first sacrificial layer 534 may comprise silicon oxide (SiO2). In an example, planarization processing may be performed on the first sacrificial layer 534 by employing a chemical mechanical polishing (CMP) process, and a surface of the initial first dielectric layer 512′ facing away from the capacitor connection structure 514 is exposed.

### S430

FIG. 5D shows an intermediate structure 500d after a portion of the initial channel structure 511′ and a portion of the initial first dielectric layer 512′ are discontinuously removed in the direction D3. FIG. 5E shows an intermediate structure 500e after an initial third isolation structure 522′ is formed. FIG. 5F shows an intermediate structure 500f after a portion of the initial third isolation structure 522′ is removed. FIG. 5G shows an intermediate structure 500g forming the channel structure 511 and a second sacrificial layer 539.

As shown in FIGS. 5C and 5D, a portion of the initial first dielectric layer 512′ and a portion of the initial channel structure 511′ may be discontinuously removed in the direction D3 by employing a lithography or etching (e.g., wet etching and/or dry etching) process. In an example, a portion of the first sacrificial layer 534 may be discontinuously removed in this process. When a material of the first isolation structure 521 comprises silicon nitride (Si3N4) and the material of the first sacrificial layer 534 comprises silicon oxide (SiO2), the first isolation structure 521 may be prevented from being discontinuously removed, so as to facilitate protection of the conductive structure 5191. For example, when there is one support structure 533 in the direction D1, the remaining portions after a portion of initial channel structure 511′ and a portion of the initial first dielectric layer 512′ are discontinuously removed in the direction D3 may be the channel structures 511 (referring to FIG. 5G).

In some implementations, as shown in FIGS. 5D and 5E, when there are a plurality of support structures 533 in the direction D1, the following operations may be executed. First, the initial third isolation structure 522′ may be formed, by employing a thin film deposition process such as CVD, PVD, ALD, or any combination thereof, in a space formed after a portion of the initial first dielectric layer 512′, a portion of the initial channel structure 511′, and a portion of the first sacrificial layer 534 are discontinuously removed. A material of the initial third isolation structure 522′ may be different from the material of the first sacrificial layer 534. For example, the material of the initial third isolation structure 522′ may comprise silicon nitride (Si3N4).

In some implementations, as shown in FIGS. 5E and 5F, the first sacrificial layer 534 may be removed by employing an etching (e.g., wet etching) process, such that the initial first dielectric layer 512′ is exposed. In an example, a portion of the initial third isolation structure 522′ may be removed by employing an etching (e.g., dry etching) process, such that a portion of the initial third isolation structure 522′ located between the adjacent support structures 533 is disconnected in the direction D1, so as to form a third isolation structure 522. Further, as shown in FIGS. 5F and 5G, the second sacrificial layer 539 may be formed by employing a thin film deposition process such as CVD, PVD, ALD, or any combination thereof, and a portion of the second sacrificial layer 539 is removed by employing an etching (e.g., dry etching) process, such that a portion of the second sacrificial layer 539 located between the adjacent support structures 533 is disconnected in the direction D1. A material of the second sacrificial layer 539 may comprise silicon oxide (SiO2). For example, the second sacrificial layer 539 may be configured to determine a size of an extending portion 5114 in the channel structure 511 in the direction D1.

In the operation S430, continuously referring to FIG. 5G, at least portions of the initial first dielectric layer 512′ and the initial channel structure 511′ covering surfaces of the capacitor dielectric layer 532 and the capacitor connection structure 514 may be removed by employing an etching (e.g., dry etching) process, to disconnect the initial channel structure 511′ covering the capacitor connection structure 514 in the direction D1, such that a plurality of channel structures 511 arranged in an array in the direction D1 and the direction D2 are formed. In an example, in a process of forming the channel structure 511, the remained initial channel structure 511′ may cover a surface of the capacitor connection structure 514, that is, the portion covering the surface of the capacitor connection structure 514 serves as the extending portion 5114 of the channel structure 511, so as to improve the reliability of an electrical connection between the channel structure 511 and the capacitor connection structure 514 and improve transmission efficiency. S440

FIG. 5H shows an intermediate structure 500h after a fourth isolation structure 540 is formed. FIG. 5I shows an intermediate structure 500i after a gate layer 513 and a portion of a fifth isolation structure 541 are formed.

In some implementations, before the gate layer 513 is formed, as shown in FIG. 5H, the fourth isolation structure 540 located between the adjacent support structures 533 and close to the capacitor connection structure 514 may be formed by employing a thin film deposition process such as CVD, PVD, ALD, or any combination thereof, and an etching process. For example, the fourth isolation structure 540 may be configured to provide a flat surface facing away from the capacitor connection structure 514, and electrically isolate the gate layer 513 (referring to FIG. 5I) to be formed and the channel structure 511.

In the operation S440, as shown in FIGS. 5G and 5I, the gate layers 513 extending along the direction D3 are formed on surfaces of the initial first dielectric layer 512′ facing away from the first sidewall 535 and the second sidewall 536. In an example, a first adhesion layer 5131 may be formed, by employing a thin film deposition process such as CVD, PVD, ALD, or any combination thereof, on the surface of the initial first dielectric layer 512′ facing away from the first sidewall 535 and the second sidewall 536, a surface of the third isolation structure 522 facing away from the first sidewall 535 and the second sidewall 536, and a surface of the fourth isolation structure 540 facing away from the capacitor connection structure 514, and a metal layer 5132 is formed on a surface of the first adhesion layer 5131. Further, portions of the first adhesion layer 5131 and the metal layer 5132 located on the surface of the fourth isolation structure 540 may be removed by employing an etching (e.g., punch etching) process, to disconnect the first adhesion layer 5131 and the metal layer 5132 in the direction D1, so as to form the gate layer 513.

In some implementations, a portion of the gate layer 513 facing away from the capacitor connection structure 514 may be removed by employing an etching process, such that a size of the gate layer 513 matches a size of the conductive structure 5191 in the direction D2. In an example, the fifth isolation structures 541 (referring to FIG. 5J) may be formed, by employing a thin film deposition process such as CVD, PVD, ALD, or any combination thereof, in a space enclosed by the gate layer 513 and on a side of the gate layer 513 facing away from the fourth isolation structure 540. For example, materials of the fourth isolation structure 540 and the fifth isolation structure 541 may be the same, and there is no distinct boundary between the fourth isolation structure and the fifth isolation structure. As an alternative, the fourth isolation structure 540 and the fifth isolation structure 541 may select different insulation materials, to which the present disclosure imposes no specific limitations.

### S450

FIG. 5J shows an intermediate structure 500j after a first dielectric layer 512 is formed. As shown in FIGS. 5I and 5J, a portion of the initial first dielectric layer 512′ corresponding to the end surface 537 may be removed by employing an etching (e.g., dry etching and/or wet etching) process, to expose the channel structure 511. In an example, portions of the initial first dielectric layer 512′ respectively located on the first sidewall 535 and the second sidewall 536 and close to the end surface 537 may further be removed.

In some implementations, the manufacturing method 400 may further comprise an operation of forming a bit line. FIG. 5K shows a semiconductor device 500 after a bit line 518 and a sixth isolation structure 542 are formed. As shown in FIG. 5K, the bit line 518 connected with a portion of the channel structure 511 corresponding to the end surface 537 may be formed, wherein the bit line 518 may extend (e.g., continuously extend) along the direction D1. In an example, the bit lines 518 and the sixth isolation structures 542 alternately arranged along the direction D3 may be formed on a top side of the intermediate structure 500j shown in FIG. 5J. The bit lines 518 may be in direct contact with a row of the channel structures 511 arranged along the direction D1, and the sixth isolation structure 542 may be configured to electrically isolate adjacent bit lines 518. For example, a size of the bit line 518 in the direction D3 may be the same as a size of each channel structure 511 in the direction D3.

According to the manufacturing method of the semiconductor device provided by this example, a transistor structure can be more compact, thereby effectively reducing footprint, increasing storage density, and facilitating improvement of an iterative miniaturization capability of a feature size of the semiconductor device. Furthermore, compared to a manufacturing method of first forming a transistor and then forming a capacitor, the manufacturing method of first forming a capacitor and then forming a transistor in an example of the present disclosure may omit processes such as thinning wafer from backside, bonding carrier wafers, and backside processing to form bit lines, such that processes can be simplified, and manufacturing costs can be saved.

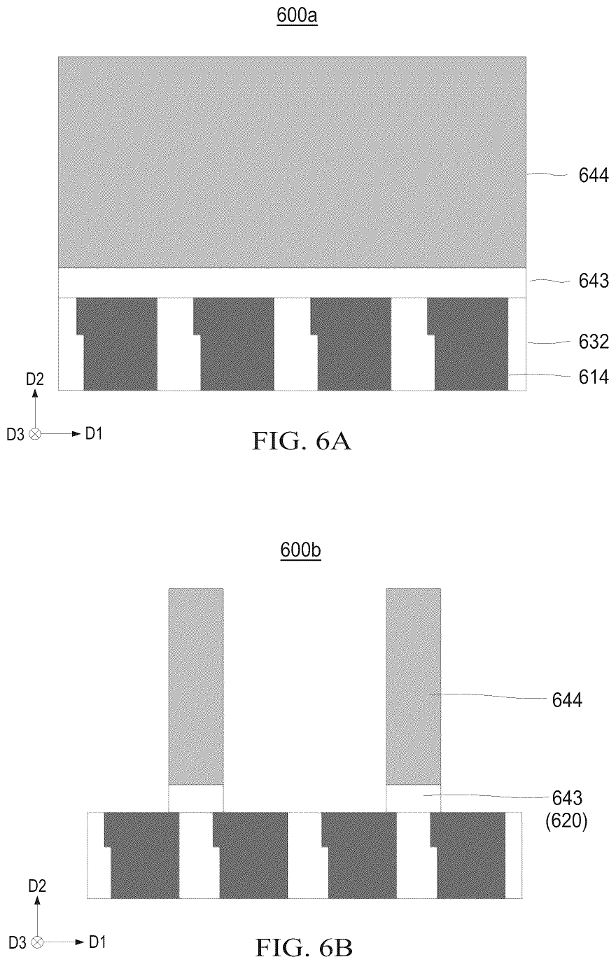

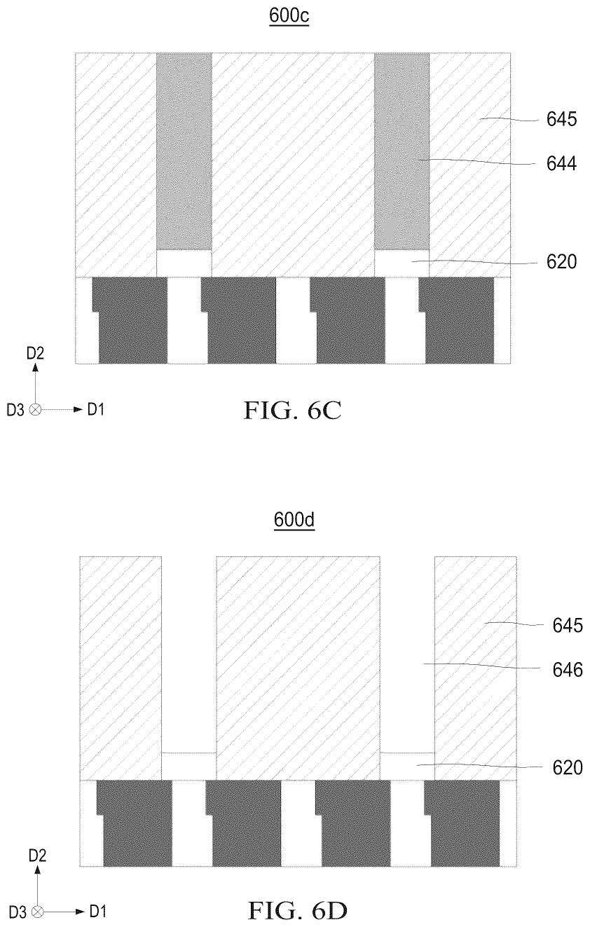

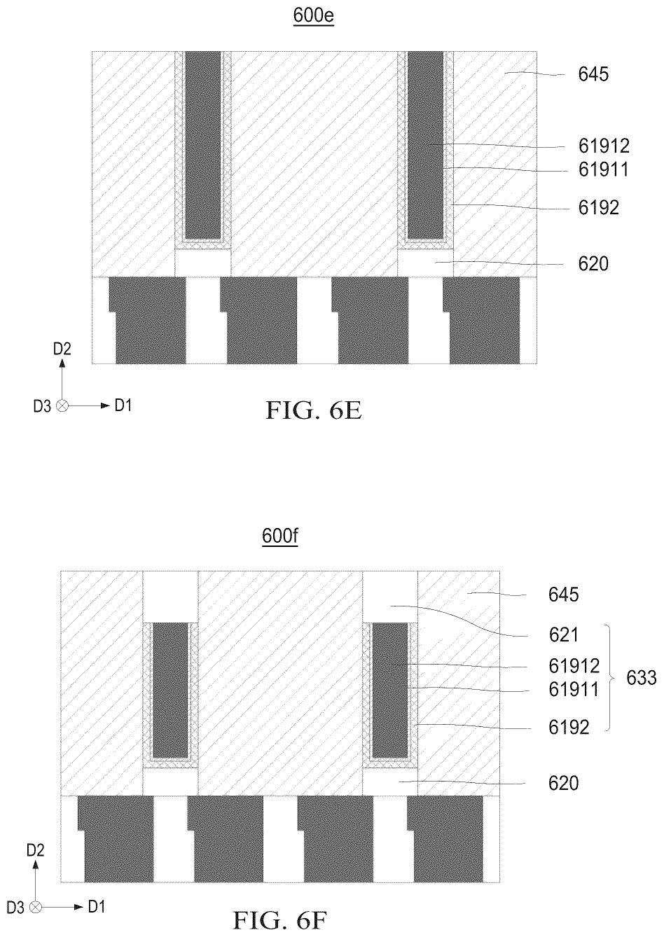

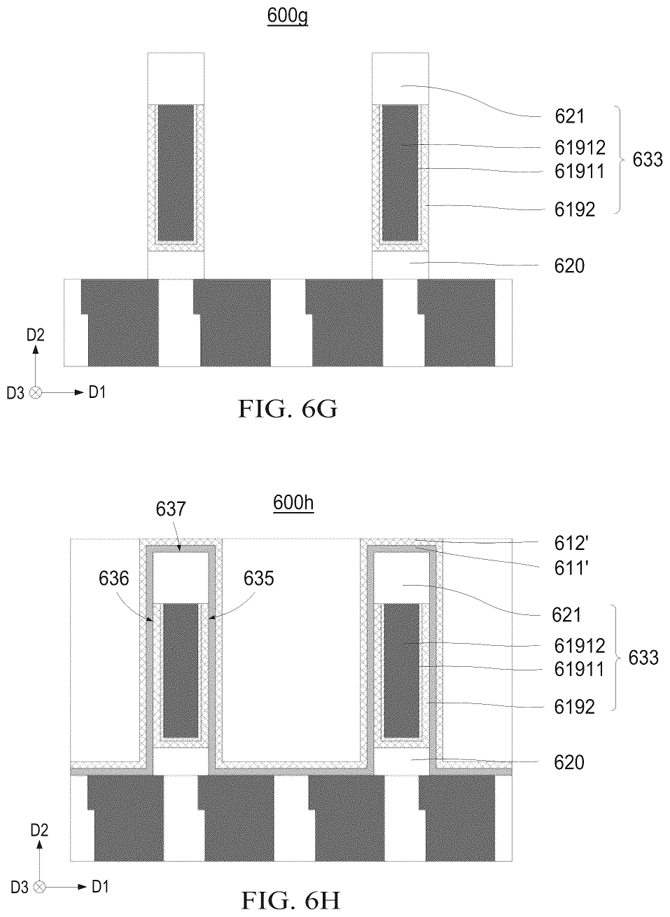

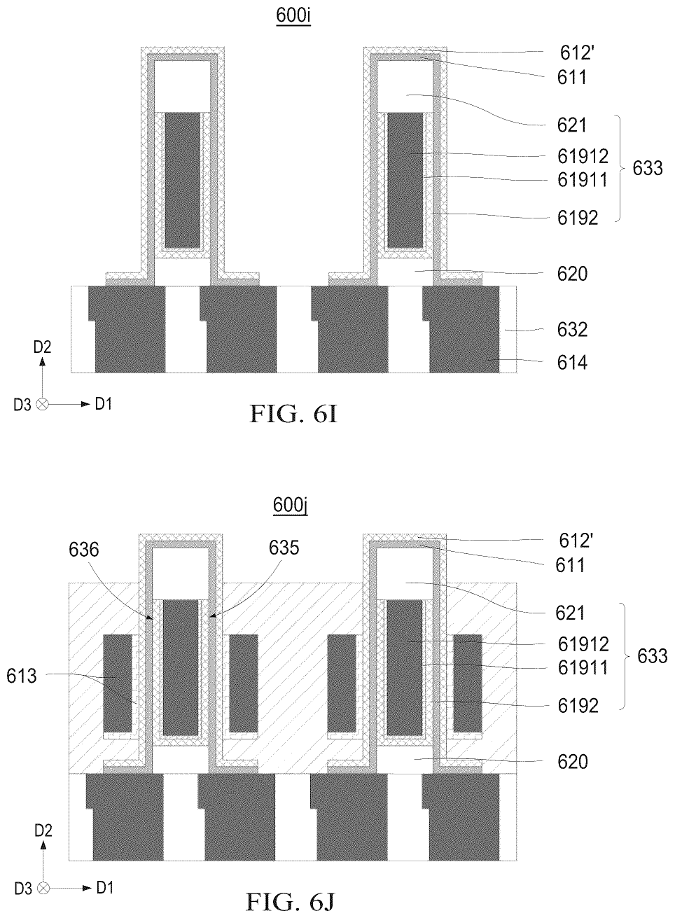

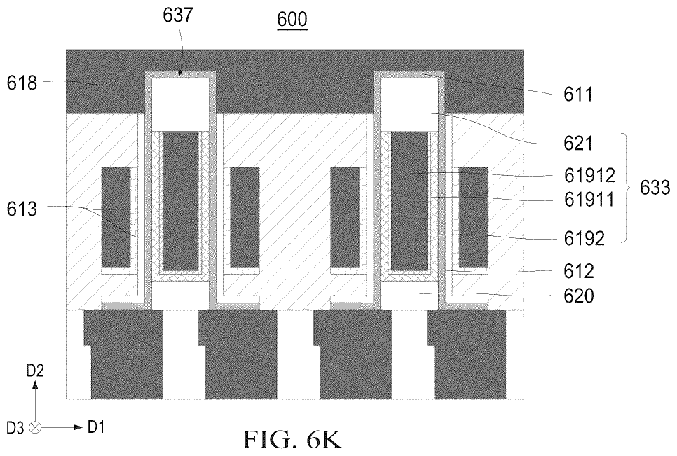

FIGS. 6A to 6K are schematic structural diagrams of a semiconductor device provided by another example of the present disclosure in a manufacturing process. For example, each intermediate structure of the semiconductor device in this example in the manufacturing process may be formed according to the manufacturing method shown in FIG. 4, and is configured to form the semiconductor device 200 shown in FIG. 2. The above-mentioned operations S410 to S450 are described below in conjunction with FIGS. 6A to 6K and FIG. 4. For the purpose of concise description, content same as that in the previous example is not repeatedly described in this example.

### S410

FIGS. 6A to 6F show intermediate structures 600a to 600f of a support structure 633 in the manufacturing process. FIG. 6G shows an intermediate structure 600g after a fourth sacrificial layer 645 is removed.

In some implementations, first, as shown in FIG. 6A, a first isolation layer 643 and a third sacrificial layer 644 may be successively formed on surfaces of a capacitor dielectric layer 632 and a capacitor connection structure 614 by employing a thin film deposition process such as CVD, PVD, ALD, or any combination thereof. Then, the third sacrificial layers 644 and the first isolation layers 643 may be patterned by employing a lithography or etching (e.g., wet etching and/or dry etching) process; and the patterned third sacrificial layer 644 and first isolation layer 643 are stacked in a direction D2, and extend (e.g., continuously extend) along a direction D3, as shown in FIG. 6B. The patterned first isolation layer 643 may serve as a first isolation structure 620. A size of the first isolation structure 620 in the direction D2 may be used for determining a position, in the direction D2, of a shielding structure to be formed. Next, as shown in FIG. 6C, the fourth sacrificial layers 645 may be formed at peripheries of the third sacrificial layer 644 and the first isolation structure 620 by employing a thin film deposition process such as CVD, PVD, ALD, or any combination thereof. For example, a material of the fourth sacrificial layer 645 is different from a material of the third sacrificial layer 644. As an example, the material of the fourth sacrificial layer 645 may comprise silicon oxide (SiO2), and the material of the third sacrificial layer 644 may comprise polycrystalline silicon (Poly-Si) or amorphous silicon (α-Si). Further, the third sacrificial layer 644 may be removed by employing an etching (e.g., wet etching) process, so as to form a trench 646 extending (e.g., for example, continuously extending) along the direction D3, as shown in FIG. 6D. For example, the first isolation structure 620 may be remained at a bottom of the trench 646. It should also be noted that since the patterned third sacrificial layer 644 and first isolation layer 643 shown in FIG. 6B are formed by etching along a direction opposite to the direction D2, sizes of the remained third sacrificial layer 644 and first isolation layer 643 in a direction D1 gradually increase along the direction opposite to the direction D2.

As another example, operations shown in FIGS. 6A to 6C may be omitted, and the fourth sacrificial layer 645 shown in FIG. 6D is patterned to form a trench (not shown) penetrating through the fourth sacrificial layer 645 and extending (e.g., continuously extending) along the direction D3, and further the first isolation structure 620 may be formed at the bottom of this trench by employing a thin film deposition process. The above-mentioned particular process modes are not limited in the present disclosure.

Further, in some implementations, as shown in FIGS. 6D and 6E, a second dielectric layer 6192 and a second adhesion layer 61911 may be successively formed on a sidewall of the trench 646 and a top surface of the first isolation structure 620 by employing a thin film deposition process such as CVD, PVD, ALD, or any combination thereof, and a metal structure 61912 is formed inside the second adhesion layer 61911 (e.g., in an enclosed space). The second adhesion layer 61911 and the metal structure 61912 may be referred to as a conductive structure. In some other implementations, after the second dielectric layer 6192 is formed, a conductive material may be directly filled inside the second dielectric layer 6192 (e.g., in an enclosed space) to form a conductive structure. In other words, the operation of forming the second adhesion layer 61911 may be omitted, to which the present disclosure imposes no specific limitations. Next, as shown in FIGS. 6E and 6F, portions of the second dielectric layer 6192, the second adhesion layer 61911, and the metal structure 61912 close to an opening of the trench 646 (referring to FIG. 6D) may be removed by employing an etching process and a thin film deposition process, and a second isolation structure 621 is formed here. The first isolation structure 620, the second isolation structure 621, the conductive structure (e.g., the second adhesion layer 61911 and the metal structure 61912), and the second dielectric layer 6192 may be referred to as the support structure 633. In addition, as described above, the conductive structure (e.g., the second adhesion layer 61911 and the metal structure 61912) and the second dielectric layer 6192 may be referred to as an shielding structure, the shielding structure can improve a coupling effect between adjacent transistors to be formed, also facilitate reduction of off-state current Ioff and sub-threshold voltage swing of the transistor, and adjust a threshold voltage Vt of the transistor, such that the electrical performance of the transistor is fully optimized.

In some implementations, the fourth sacrificial layer 645 may be removed by employing an etching (e.g., wet etching) process, so as to form the intermediate structure 600g shown in FIG. 6G.

### S420

FIG. 6H shows an intermediate structure 600h forming an initial channel structure 611′ and an initial first dielectric layer 612′.

In this operation, as shown in FIG. 6H, the initial channel structure 611′ covering a first sidewall 635, a second sidewall 636, and an end surface 637 of the support structure 633 may be formed, and the initial first dielectric layer 612′ is formed on a surface of the initial channel structure 611′.

### S430

FIG. 6I shows an intermediate structure 600i after a channel structure 611 is formed.

In this operation, a portion of the initial channel structure 611′ and a portion of the initial first dielectric layer 612′ are discontinuously removed in a direction D3. In some implementations, as shown in FIG. 6I, at least portions of the initial first dielectric layer 612′ and the initial channel structure 611′ covering surfaces of the capacitor dielectric layer 632 and the capacitor connection structure 614 may be removed by employing an etching (e.g., dry etching) process, to disconnect the initial channel structure 611′ covering the capacitor connection structure 614 in a direction D1, such that the channel structure 611 is formed.

### S440

FIG. 6J shows an intermediate structure 600j after a gate layer 613 is formed.

In this operation, as shown in FIG. 6J, the gate layer 613 extending (e.g., continuously extending) along the direction D3 is formed on a surface of the initial first dielectric layer 612′ facing away from the first sidewall 635 and the second sidewall 636.

### S450

FIG. 6K shows a semiconductor device 600 after a first dielectric layer 612 and a bit line 618 are formed.

In this operation, as shown in FIGS. 6J and 6K, a portion of the initial first dielectric layer 612′ corresponding to the end surface 637 may be removed by employing etching (e.g., dry etching and/or wet etching), to expose the channel structure 611.

In some implementations, the bit line 618 connected with a portion of the channel structure 611 corresponding to the end surface 637 may be formed, wherein the bit line 618 may extend (e.g., continuously extend) along the direction D1.

According to the manufacturing method of the semiconductor device provided by this example, a transistor structure can be more compact, thereby effectively reducing footprint, increasing storage density, and also being able to improve an iterative miniaturization capability of a feature size of the semiconductor device. Furthermore, according to the manufacturing method of first forming a capacitor and then forming a transistor, processes can be simplified, and manufacturing costs can be saved.

Although the process method of forming the support structure 533 or 633 is described in detail above, the support structure may be composed of one or more insulation materials, and any known process method in the art may be employed to form the support structure extending the direction D3, so as to provide support for the subsequently-formed initial channel structure and initial first dielectric layer, to which the present disclosure imposes no specific limitations.

The above descriptions are merely the descriptions of implementations of the present disclosure and technical principles used. Those skilled in the art should understand that the protection scope of the present disclosure is not limited to the technical solutions formed by specific combinations of the above technical features, and meanwhile, should also encompass other technical solutions formed by any combinations of the above technical features or equivalent features thereof without departing from the technical concept, for example, technical solutions formed by interchanging the above features with the technical features having similar functions as disclosed (but not limited to those) in the present disclosure.

What is claimed is:

1. A semiconductor device, comprising:
channel structures, wherein at least one of the channel structures comprises:
a first side portion and a second side portion arranged along a first direction; and
a connection portion connected to first end portions of the first side portion and the second side portion in a second direction;
first dielectric layers located on surfaces of the first side portion and the second side portion that are opposite to each other; and
gate layers located on surfaces of the first dielectric layers and extending along a third direction;
wherein the first direction, the second direction, and the third direction intersect with each other.

2. The semiconductor device of claim 1, wherein the channel structures are arranged as being spaced apart in the first direction, and connection portions in each one of the channel structures are not in contact with each other.

3. The semiconductor device of claim 1, further comprising:
second end portions of the first side portion and the second side portion facing away from the connection portion;
wherein a spacing distance between the first end portions of the first side portion and the second side portion, is smaller than a spacing distance between the second end portions of the first side portion and the second side portion.

4. The semiconductor device of claim 1, wherein surfaces of the gate layers close to the first side portion and the second side portion are concavo-convex-shaped on a plane perpendicular to the second direction.

5. The semiconductor device of claim 1, further comprising:
a shielding structure located between the first side portion and the second side portion and comprising:
a conductive structure extending along the third direction; and
second dielectric layers located between the conductive structure and the first side portion and between the conductive structure and the second side portion.

6. The semiconductor device of claim 5, further comprising:
a first isolation structure located between the first side portion and the second side portion and on a side of the conductive structure facing away from the connection portion; and
a second isolation structures located between the connection portion and the conductive structure and on a side of the conductive structure close to the connection portion.

7. The semiconductor device of claim 1, further comprising:
capacitor connection structures respectively connected to second end portions of the first side portion and the second side portion facing away from the connection portion.

8. The semiconductor device of claim 7, wherein at least one of the channel structures further comprises extending portions located on the second end portions, and the extending portions respectively extend along the first direction and directions facing away from the first side portion and the second side portion, and are respectively in contact with the capacitor connection structures.

9. The semiconductor device of claim 7, further comprising:
an outer electrode layer located on a side of respective one of the capacitor connection structures facing away from the channel structures;
an inner electrode located in the outer electrode layer; and
an insulation layer located between the outer electrode layer and the inner electrode;
wherein respective one of the capacitor connection structures is connected with the inner electrode.

10. The semiconductor device of claim 1, further comprising:
a bit line extending along the first direction and connected with the connection portion.

11. The semiconductor device of claim 1, wherein materials of the first side portion, the second side portion, and the connection portion comprise a metal oxide semiconductor.

12. The semiconductor device of claim 11, wherein the metal oxide semiconductor comprises an indium gallium zinc oxide.

13. The semiconductor device of claim 1, wherein:
a size range of the first side portion in the first direction is 3 nm-10 nm; and
a size range of the second side portion in the first direction is 3 nm-10 nm.

14. A memory system, comprising:
a semiconductor device which comprises:
channel structures, wherein at least one of the channel structures comprises:
a first side portion and a second side portion arranged along a first direction; and
a connection portion connected to first end portions of the first side portion and the second side portion in a second direction;
first dielectric layers located on surfaces of the first side portion and the second side portion that are opposite to each other; and
gate layers located on surfaces of the first dielectric layers and extending along a third direction;
wherein the first direction, the second direction, and the third direction intersect with each other, and
a controller coupled to the semiconductor device and configured to control the semiconductor device to store data.

15. A method of forming a semiconductor device, comprising:
forming a support structure extending along a third direction, wherein the support structure has a first sidewall and a second sidewall opposite to each other in a first direction and an end surface in a second direction;
forming an initial channel structure covering the first sidewall, the second sidewall, and the end surface, and forming an initial first dielectric layer on a surface of the initial channel structure;
discontinuously removing a portion of the initial channel structure and a portion of the initial first dielectric layer in the third direction to form a plurality of channel structures;
forming gate layers extending along the third direction on surfaces of the initial first dielectric layer facing away from the first sidewall and the second sidewall; and
removing a portion of the initial first dielectric layer corresponding to the end surface to expose the channel structures;
wherein the first direction, the second direction, and the third direction intersect with each other.

16. The method of claim 15, wherein forming the support structure extending along the third direction comprises:
forming a first isolation structure, a conductive structure, and a second isolation structure sequentially arranged along the second direction, wherein the first isolation structure, the conductive structure, and the second isolation structure all extend along the third direction; and
forming second dielectric layers on sidewalls of the conductive structure opposite to each other in the first direction to form the support structure.

17. The method of claim 15, wherein forming the support structure extending along the third direction comprises:
etching a sacrificial layer to form a trench extending along the third direction, wherein a first isolation structure is formed at a bottom of the trench;
forming second dielectric layers on a sidewall of the trench and a top surface of the first isolation structure, and forming a conductive structure inside the second dielectric layers; and
forming a second isolation structure at a top of the trench to form the support structure.

18. The method of claim 15, wherein before forming the support structure extending along the third direction, the manufacturing method further comprises:
forming an outer electrode layer on a side of a substrate;
forming a plurality of inner electrodes in the outer electrode layer; and
respectively forming a plurality of insulation layers between the outer electrode layer and the plurality of inner electrodes.

19. The method of claim 18, further comprising:
forming a capacitor dielectric layer covering the plurality of inner electrodes and the plurality of insulation layers; and
forming a plurality of capacitor connection structures penetrating through the capacitor dielectric layer and respectively connected with the plurality of inner electrodes, wherein at least a portion of the support structure is located between adjacent capacitor connection structures in the first direction.

20. The method of claim 19, wherein the adjacent support structures are spaced apart with two of the capacitor connection structures in the first direction;
wherein forming an initial channel structure covering the first sidewall, the second sidewall, and the end surface, and forming the initial first dielectric layer on the surface of the initial channel structure comprises:
forming the initial channel structure on surfaces of the capacitor dielectric layer and the capacitor connection structures;
wherein discontinuously removing the portion of the initial channel structure and the portion of the initial first dielectric layer in the third direction to form a plurality of channel structures further comprises:
removing at least a portion of the initial channel structure covering the surfaces of the capacitor dielectric layer and the capacitor connection structures to disconnect the initial channel structure covering the capacitor connection structures in the first direction.
